(19) United States
(12) Patent Application Publication
(10) Pub. No.: US 2008/0077835 A1
(43) Pub. Date: Mar. 27, 2008

(54) Automatic Test Equipment Receiving Diagnostic Information from Devices with Built-in Self Test

(76) Inventors: A. Jay Khoche, San Jose, CA (US); Klaus-Dieter Hilliges, Shanghai (CN)

Correspondence Address: VERIGY, 4700 INNOVATION WAY, BLDG D1, FORT COLLINS, CO, 80528, US

(21) Appl. No.: 11/535,909

(22) Filed: Sep. 27, 2006

(51) Int. Cl. G01R 31/28

(52) U.S. Cl. 714/733

(57) ABSTRACT

Automatic test equipment capable of receiving diagnostic information from a device under test having a built-in self-test system (BIST) and a diagnostic information collector in which the diagnostic information collector temporarily stores diagnostic patterns output by the BIST and provides a fault indication upon detecting a fault in the device under test. Such ATE comprises a device interface connectable to the device under test, a processing system and processing channels. The processing channels are each connected to the device interface and to the processing system and comprise test channels, a fault indication channel and a diagnostic information channel. The test channels are interoperable with the BIST to subject the device under test to a sequence of tests. The fault indication channel is connected to receive the fault indication from the device interface. The diagnostic information channel is operable in response to the fault indication received via the fault indication channel to receive from the device interface at least some of the diagnostic patterns temporarily stored in the device under test as the diagnostic information.

### RELATED APPLICATIONS

This disclosure is related to the following United States patent applications filed on the filing date of this disclosure: Ser. No. ______ of Khoche et al. entitled Diagnostic Information Capture from Logic Devices with Built-in Self Test (Docket no. 10051609) and Ser. No. ______ of Khoche et al. entitled Diagnostic Information Capture from Memory Devices with Built-in Self Test (Docket no. 10060523). The above disclosures are assigned to the assignee of this disclosure and are incorporated herein by reference.

### BACKGROUND

The ever-increasing complexity of integrated circuits has led to integrated circuits being designed with a built-in self-test system (BIST) to facilitate testing each device under test during manufacture. Automatic test equipment (ATE) is still used to test the device under test, but the automatic test equipment simply controls the BIST and receives a test result generated by the BIST. The ATE evaluates the test result to categorize the device under test as good or bad.

A logic device is an integrated circuit that comprises a logic circuit. In a logic device that incorporates a built-in self test system, the built-in self test system typically comprises scan chains that convey stimulus vectors from a stimulus source to various parts of the logic device under test and convey responses from various parts of the logic device under test to a digital signature generator. The digital signature generator performs data compression on the responses generated by the logic circuits in response to each test to generate a single digital signature that represents all the responses generated by the test. At the end of the test sequence, the BIST outputs the digital signature to the host ATE as the test result for the logic device under test. The ATE compares the digital signature with an expected signature. A difference between the digital signature and the expected signature indicates that the device under test is faulty.

The data compression process applied to the responses substantially reduces the data flow from the BIST to the ATE but only allows the ATE to categorize the logic device under test as a whole as good or bad. The data compression process prevents the ATE from identifying the portion of the logic device under test that has caused the logic device under test as a whole to fail the test. Such information is highly desirable, especially to allow process optimization during production ramp-up but also during on-going production to facilitate process control.

A memory device is an integrated circuit that comprises a memory circuit. In a memory device that incorporates a built-in self test system, the BIST typically comprises a pattern generator, an address generator and a control generator. The pattern generator, address generator and control generator respectively provide test patterns and expected patterns, addresses and control signals via respective multiplexers to the data inputs, address inputs and control inputs of the memory circuit. The test patterns are written at memory locations in the memory circuit and respective output patterns are read out from the memory locations. The output pattern read from each memory location is compared with a corresponding expected pattern identical to the test pattern that was written at the memory location to determine whether a difference exists. Differences, if any, detected between the output patterns and the corresponding expected patterns are accumulated in the BIST to generate a cumulative difference. At the end of the test sequence, the cumulative difference is output to the host ATE as the test result for the memory device under test. The ATE evaluates the test result to determine whether the test result indicates that the testing has detected a difference between any of the output patterns and its corresponding expected pattern. A difference indicates that the memory device under test is faulty.

Outputting the test result from the memory device under test to the host ATE at the end of the test sequence significantly reduces the data flow from the BIST to the host ATE. However, outputting the test result only allows the ATE to categorize the memory device under test as a whole as good or bad. The data compression involved in generating the cumulative difference used as the test result prevents the ATE from identifying the portion of the memory circuit that has caused the memory device under test as a whole to fail the test. Again, such information is highly desirable, especially to allow process optimization during production ramp-up but also during on-going production to facilitate process control.

Conventional automatic test equipment used to test devices with built-in test systems operates deterministically. After a device under test has been connected to the ATE, the ATE issues a control signal to the BIST incorporated in the device under test to command the BIST to begin performing a test sequence to test the device under test. The number of ATE operational cycles required for the BIST to execute the test sequence is known to the ATE. After the ATE has performed the prescribed number of operational cycles, the ATE performs a test result segment of its main test routine in which it receives the test result generated by the BIST. Alternatively, after the ATE has performed the prescribed number of operational cycles, the test result segment of the main routine issues a command to the BIST that causes the BIST to output the test result to the ATE. The ATE then evaluates the test result to determine whether the device under test has failed at least one test in the test sequence and categorizes the device under test appropriately.

In patent applications entitled Diagnostic Information Capture from Logic Devices with Built-in Self Test (Docket no. 10051609) and Diagnostic Information Capture from Memory Devices with Built-in Self Test (Docket no. 10060523), the above-named inventors disclose systems that enable devices with built-in self-test systems to provide diagnostic information. However, to economize on storage in the device under test, such systems output the diagnostic information immediately after each fault is detected. Since a fault can be detected at any arbitrary point in the test sequence, diagnostic information relating to the fault can be output to the ATE at any arbitrary point in the test sequence.

Conventional automatic test equipment that operates deterministically and that only operates to receive the test result output by the device under test at the end of the test sequence is incapable of receiving diagnostic information that is output by the device under test at an arbitrary point in the test sequence. What is needed, therefore, is automatic test equipment capable of receiving diagnostic information output from a device under test at an arbitrary point in the test sequence.

### BRIEF DESCRIPTION OF THE DRAWINGS

FIG. 1 is a block diagram showing an example of a system comprising an example of automatic test equipment in accordance with an embodiment of the invention that receives diagnostic information output from a logic device under test having a built-in test system (BIST).

FIG. 2 is a block diagram showing an example of a diagnostic information collector that may be used as the diagnostic information collector in the logic device shown in FIG. 1.

FIG. 3 is a block diagram showing an example of a system comprising an example of automatic test equipment in accordance with an embodiment of the invention that receives diagnostic information output from a memory device under test having a BIST.

FIG. 4A is a block diagram showing an example of a diagnostic information collector that may be used as the diagnostic information collector in the memory device shown in FIG. 3.

FIG. 4B is a block diagram showing another example of a diagnostic information collector that may be used as the diagnostic information collector in the memory device shown in FIG. 3.

FIG. 5 is a flow chart showing an example of a method in accordance with an embodiment of the invention of operating the ATE shown in FIG. 1 or the ATE shown in FIG. 3 to obtain diagnostic information from a device under test having a BIST and a diagnostic information collector.

FIG. 6 is a block diagram showing an example of ATE in accordance with an embodiment of the invention for receiving diagnostic information from a device under test.

FIG. 7 is a flow chart showing an example of a method in accordance with an embodiment of the invention of operating automatic test equipment to obtain diagnostic information from a device under test having a BIST and a diagnostic information collector.

FIG. 8 is a block diagram showing part of an example of a memory device having a BIST and a diagnostic information collector that outputs diagnostic patterns to the ATE for temporary storage, and additionally shows an example of ATE in accordance with an embodiment of the invention that may be used to receive the diagnostic patterns from such a memory device under test.

### DETAILED DESCRIPTION

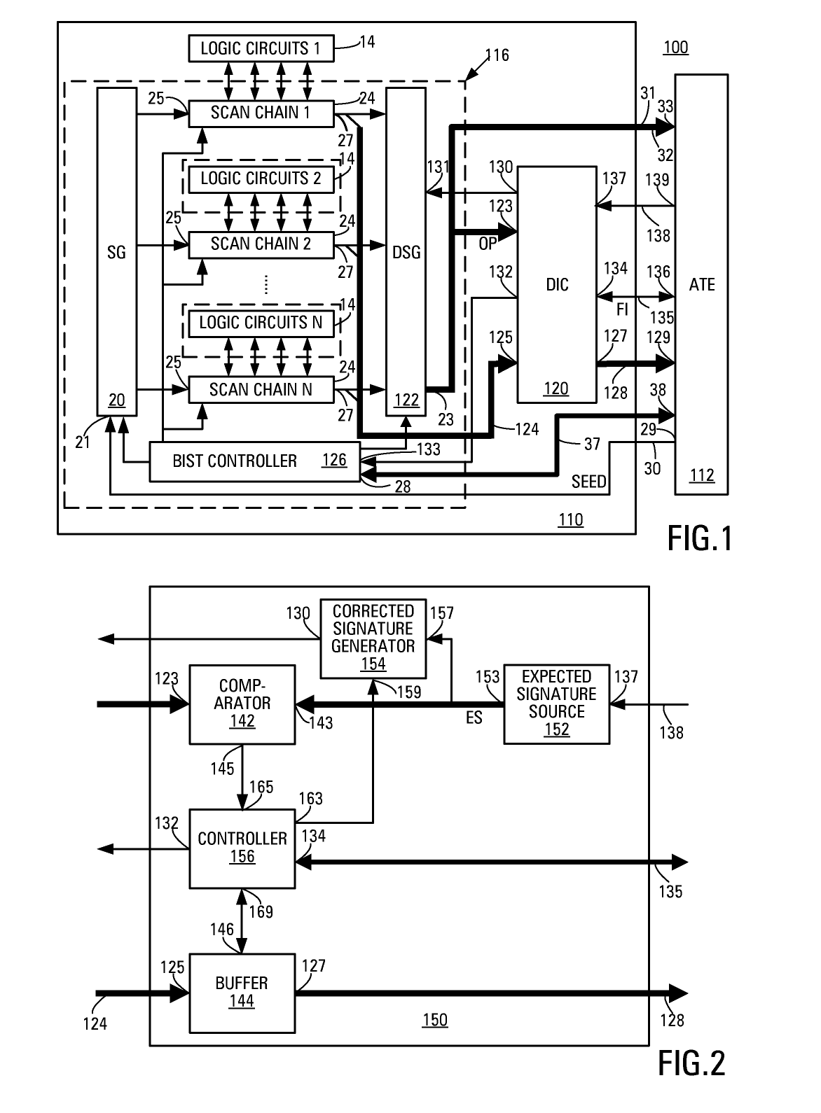

FIG. 1 is a block diagram showing an example of a system 100 comprising a logic device under test 110 and an example of automatic test equipment 112 in accordance with an embodiment of the invention that receives diagnostic information output from the logic device under test.

Logic device 110 comprises logic circuits 14, a built-in self-test system (BIST) 116 and a diagnostic information collector (DIC) 120. BIST 116 performs a sequence of tests to test logic circuits 14. When a test performed by BIST 116 generates a response indicating a fault in logic circuits 14, logic device under test 110 provides diagnostic information for output to ATE 112. Since BIST 116 can detect a fault at any point in the test sequence, ATE 112 is structured to behave non-deterministically to enable it to receive the output diagnostic information.

BIST 116 is a pseudo-random BIST or any other deterministic BIST, including any BIST that employs reseeding techniques. Examples of commercially-available BISTs include those sold by Synopsys, Inc., Mountain View, Calif. under the name SoCBIST, and those sold by Mentor Graphics Corp., Wilsonville, Oreg. under the registered trademark TestKompress.

The example of BIST 116 shown in FIG. 1 comprises a stimulus generator (SG) 20, a digital signature generator (DSG) 122, scan chains 24 and a BIST controller 126. Stimulus generator 20 has a seed input 21 via which it receives one or more seeds from a seed output 29 of ATE 112 via a seed path 30.

Each of the scan chains 24 has an input 25 connected to stimulus generator 20 and an output 27 connected to digital signature generator 122. The output 27 of each of the scan chains 24 is additionally connected to a respective input of a diagnostic pattern bus 124. Points along the lengths of scan chains 24 are coupled to logic circuits 14.

Scan chains 24 operate to shift one or more stimulus vectors along the scan chains and to apply the stimulus vectors to logic circuits 14. Scan chains 24 additionally operate to capture from logic circuits 14 the responses generated by the logic circuits in response to each stimulus vector and to shift the captured responses towards digital signature generator 122 and diagnostic pattern bus 124 connected to the outputs 27 of the scan chains. The responses output by each output shift operation performed by scan chains 24 collectively constitute a respective diagnostic pattern.

Digital signature generator 122 has a digital signature output 23 and additionally has a respective input connected to the output of each scan chain 24. Digital signature output 23 is internally connected to a test result output 31 of logic device 110. Digital signature generator 122 receives the diagnostic pattern output by each output shift operation performed by scan chains 24. After receiving each diagnostic pattern, digital signature generator 122 generates a new digital signature and outputs at least part of such digital signature at digital signature output 23 as a respective representative signature. The digital signature and the representative signature depend not only on the diagnostic pattern output by the most-recent output shift operation performed by scan chains 24 but also on diagnostic patterns output by previous output shift operations performed by scan chains 24.

At the end of the test sequence performed by BIST 116, some embodiments of digital signature generator 122 output the complete digital signature from digital signature output 23 to test result output 31 as the test result for logic device under test 110. Logic device under test 110 has the above-mentioned test result output 31 and provides the test result at test result output 31 to provide compatibility with conventional test routines executed by ATE 112. Test result output 31 may be omitted in versions of logic device 110 intended for testing by an embodiment of ATE 112 that executes a modified logic test routine having a test result segment capable of determining a test result for logic device under test 110 without the ATE receiving a test result from the logic device under test itself. For example, the ATE can determine a test result for the logic device under test by determining whether it received a fault indication or whether it received diagnostic information while it was testing the logic device under test.

Diagnostic information collector 120 has a representative signature input 123, a diagnostic pattern input 125, a diagnostic information output 127, a fault indication port 134 and an expected signature information input 137. Representative signature input 123 is connected to the digital signature output 23 of digital signature generator 122. Diagnostic pattern input 125 is connected to the end of diagnostic pattern bus 124 remote from scan chains 24.

In operation, diagnostic information collector 120 receives at diagnostic pattern input 125 the diagnostic pattern output by each output shift operation performed by scan chains 24 and temporarily stores the diagnostic pattern such that a most-recently output subset of the diagnostic patterns is stored. The most-recently output subset of the diagnostic patterns is composed of fewer than all of the diagnostic patterns generated by logic circuits 14 in response to the stimulus vectors. Consequently, fewer than all of the diagnostic patterns that would be generated during the entire test sequence are stored. This significantly reduces the storage needed for the diagnostic patterns. Additionally, the diagnostic information collector receives at representative signature input 123 the representative signature output by digital signature generator 122 after each output shift operation performed by scan chains 24. Diagnostic information collector 120 determines whether each representative signature received at representative signature input 123 is a fault-indicating representative signature. When it determines that a representative signature is a fault-indicating representative signature, diagnostic information collector 120 provides a fault indication FI at fault indication port 134. Fault indication FI indicates that BIST 116 has detected a fault in logic device under test 110 and that diagnostic information temporarily stored in diagnostic information collector 120 is available. Diagnostic information collector 120 then outputs the stored diagnostic information via diagnostic information output 127.

ATE 112 has a seed output 29, test result input 33, a control port 38, diagnostic information input 129, a fault indication port 136 and an expected signature information output 139. A test result path 32 connects test result input 33 to the test result output 31 of logic device under test 110. The test result input and test result path may be omitted from embodiments of ATE 112 capable of determining a test result for logic device under test 110 without receiving a test result from logic device under test 110 itself.

A seed path 30 connects seed output 29 to the seed input 21 of stimulus generator 20. A control path 37 connects control port 38 to a control port 28 of BIST controller 126. BIST controller 126 controls the operation of BIST 116 in response to control signals provided by ATE 112 via control path 37 and additionally provides status information to ATE 112 via control path 37. A diagnostic information path 128 connects diagnostic information input 129 to the diagnostic information output 127 of diagnostic information collector 120. A fault indication path 135 connects fault indication port 136 to the fault indication port 134 of diagnostic information collector 120. An expected signature information path 138 connects expected signature information output 139 to the expected signature information input 137 of diagnostic information collector 120.

In operation to test logic device under test 110, ATE 112 executes a main test routine that causes ATE 112 to perform conventional testing operations. Near the beginning of the main test routine, ATE 112 provides control signals to BIST controller 126 via control path 37. The control signals cause BIST controller 126 to initialize BIST 116 and command BIST 116 to perform a sequence of tests to test the logic circuits 14 of logic device under test 110. As BIST 116 performs the sequence of tests, the main test routine executed by ATE 112 causes the ATE to perform other testing operations. At the end of the sequence of tests, the digital signature generator 122 of BIST 116 outputs the entire digital signature from digital signature output 23 to test result output 31 as the test result for logic device under test 110. Test result output 31 is connected to the test result input 33 of ATE 112 by test result path 32. The main test routine performed by ATE 112 includes a test result segment that is performed concurrently with the end of the test sequence executed by BIST 116. The test result segment causes ATE 112 to receive the test result at test result input 33, to evaluate the test result to categorize logic device under test 110 as good or bad and to provide an output indicating the category (good or bad) of logic device under test 110.

Alternatively, the test result segment of the main test routine performed by ATE 112 may determine a test result for logic device under test 110 without the need for device under test 110 to provide a test result to the ATE. For example, the test result segment may determine whether ATE 112 received fault indication FI at fault indication port 136 or whether ATE 112 received diagnostic information at diagnostic information input 129 while it was testing logic device under test 110. The ATE not receiving a fault indication or not receiving diagnostic information while it was testing logic device under test 110 causes the test result segment to categorize the logic device under test as good.

More specifically, at the beginning of the sequence of tests performed by BIST 116, the main test routine performed by ATE 112 causes ATE 112 to provide a seed to the seed input 21 of stimulus generator 20 via seed output 29 and seed path 30. Then, stimulus generator 20 generates a sequence of stimulus vectors based the seed. Typically, stimulus generator 20 is a linear feedback shift register (LFSR). Stimulus generator 20 outputs each stimulus vector in the sequence of stimulus vectors to the inputs 25 of scan chains 24. Scan chains 24 shift the stimulus vectors into logic circuits 14 and apply the stimulus vectors to logic circuits 14. The logic circuits then generate respective responses to the stimulus vectors. Scan chains 24 capture the responses of logic circuits 14 to the stimulus vectors and shift the responses towards their respective outputs 27. The responses output by each output shift operation performed by scan chains 24 collectively constitute a respective diagnostic pattern. The diagnostic pattern is input to digital signature generator 122 and to diagnostic information collector 120. In the example shown, digital signature generator 122 is embodied as a multiple input shift register (MISR). In other embodiments, digital signature generator 122 is embodied as a combinatorial network known as an X-Compactor.

After each output shift operation performed by scan chains 24, digital signature generator 122 generates a digital signature representing the diagnostic patterns received from scan chains 24. Digital signature generator 122 outputs at least part of such digital signature as a respective representative signature to the representative signature input 123 of diagnostic information collector 120. Each representative signature output by digital signature generator 122 constitutes a respective output pattern OP generated by BIST 116 as a result of testing logic device under test 110.

The number of bits in each digital signature generated by digital signature generator 122 is typically equal to the number of scan chains 24. As noted above, after each output shift operation performed by scan chains 24, digital signature generator 122 generates a new digital signature and outputs at least part of such digital signature to diagnostic information collector 120 as the representative signature. Diagnostic information collector 120 compares each representative signature output by digital signature generator 122 with a corresponding expected signature to determine whether the representative signature is a fault-indicating representative signature that indicates a fault. In one embodiment, digital signature generator 122 outputs the most-significant bit (MSB) or the least-significant bit (LSB) of each digital signature as a respective single-bit representative signature and diagnostic information collector 120 compares such single-bit representative signature with a respective single-bit expected signature. In this embodiment, latency between a fault-indicating response being received at an input of digital signature generator 122 and the digital signature generator outputting a resulting single-bit fault-indicating representative signature is a maximum. In terms of output shift operations performed by scan chains 24, the latency of this single-bit embodiment is equal the number of bits in the digital signature generated by digital signature generator 122. In another embodiment, to reduce latency compared with that of using a single-bit representative signature, digital signature generator 122 is provided with taps along its length and outputs multiple representative bits of the digital signature as a multi-bit representative signature. Diagnostic information collector 120 compares such multi-bit representative signature with a respective multi-bit expected signature having an equal number of bits. Latency is minimized by digital signature generator 122 outputting all the bits of each digital signature as the representative signature. Increasing the number of bits in the representative signature reduces latency but potentially increases the demand for communication bandwidth between logic device under test 110 and ATE 112 for the expected signature. The optimum number of bits in the representative signature output by digital signature generator 122 is therefore based on a trade-off between latency and communication bandwidth for given embodiments of logic device 110 and ATE 112.

Diagnostic information collector 120 additionally determines whether each output pattern, i.e., each representative signature, received from the digital signature generator 122 of BIST 116 is a fault-indicating representative signature. When diagnostic information collector 120 determines that the representative signature is a fault-indicating representative signature, it provides fault indication FI. The main test routine executed by ATE 112 provides expected signature information at expected signature information output 139 for diagnostic information collector 120 to use directly or indirectly in making this determination. In some embodiments, the test routine performed by ATE 112 provides an expected signature corresponding to each representative signature received by diagnostic information collector 120 as the expected signature information. In other embodiments, diagnostic information collector 120 calculates from the expected signature information an expected signature corresponding to each representative signature it receives. Diagnostic information collector 120 compares the representative signature it receives after each output shift operation performed by scan chains 24 with the corresponding expected signature. A representative signature that differs from its corresponding expected signature is a fault-indicating representative signature that indicates that at least one of the diagnostic patterns represented by the representative signature is a fault-indicating diagnostic pattern.

Diagnostic information collector 120 additionally receives the diagnostic pattern output by each output shift operation performed by scan chains 24 and temporarily stores the diagnostic pattern such that a most-recently output subset of the diagnostic patterns is stored. The most-recently output subset of the diagnostic patterns is composed of fewer than all of the diagnostic patterns generated by logic circuits 14 in response to the stimulus vectors. Embodiments of digital signature generator 122 typically have an operational latency in which the digital signature generator receives a fault-indicating diagnostic pattern from scan chains 24 but may not output a corresponding fault-indicating representative signature until the scan chains have performed several output shift operations. The size of the most-recently output subset of the diagnostic patterns, i.e., the number of diagnostic patterns that are temporarily stored, depends at least in part on the maximum latency of digital signature generator 122.

In an example in which digital signature generator 122 is embodied as a multiple input shift register (MISR) and in which the representative signatures are each a single bit, the scan chains will perform as many as N output shift operations before a fault-indicating response output by the scan chain most distant from the digital signature output of the MISR (the scan chain labelled scan chain 1 in the example shown in FIG. 1) will cause the MISR to generate a fault-indicating representative signature, where N is the number of stages in the MISR. In such example, diagnostic information collector 120 stores the diagnostic patterns output by at least N output shift operations to prevent the fault-indicating diagnostic pattern from being overwritten by another, subsequently-stored diagnostic pattern before the output shift operations are stopped by the fault-indicating response finally causing the MISR to generate the fault-indicating representative signature that causes diagnostic information collector 120 to provide fault indication FI.

When ATE 112 tests a fault-free example of logic device under test 110, each representative signature received by diagnostic information collector 120 as an output pattern is identical to its corresponding expected signature. As a result, BIST 116 reaches the end of the test sequence without diagnostic information collector 120 providing fault indication FI. Concurrently with the end of the test sequence performed by BIST 116, ATE 112 executes the above-described test result segment that constitutes part of the main test routine to receive the test result provided by BIST 116 or otherwise to determine a test result for logic device under test 110. The test result segment evaluates the test result to categorize logic device under test 110 as good or bad. In this example, the evaluation of the final result categorizes logic device under test 110 as good.

When ATE 112 tests an example of logic device under test 110 having at least one fault, at least one representative signature output by digital signature generator 122 as a respective output pattern differs from its corresponding expected signature. For each representative signature that differs from its corresponding expected signature, diagnostic information collector 120 outputs fault indication FI to the fault indication port 136 of ATE 112. Fault indication FI indicates to ATE 112 that BIST 116 has output a fault-indicating diagnostic pattern and that diagnostic information is available. In response to fault indication FI, ATE 112 suspends execution of the main test routine and executes a diagnostic information receiving routine in which it receives from the diagnostic information output 127 of diagnostic information collector 120 the diagnostic patterns output as diagnostic information. The output diagnostic patterns are at least some of those temporarily stored in the logic circuit under test. In the example shown, diagnostic information collector 120 outputs the stored diagnostic patterns to the diagnostic information input 129 of ATE 112 via diagnostic information path 128. Once ATE 112 has received the diagnostic information output by logic device under test 110, ATE 112 resumes executing the main test routine, and BIST 116 continues to test logic device under test 110. When BIST 116 reaches the end of the test sequence, ATE 112 concurrently executes the above-described test result segment of the main test routine to categorize logic device under test 110 as good or bad. In this example, the test result segment categorizes logic device under test 110 as bad.

FIG. 1 additionally shows some optional additional elements of system 100 and logic device 110. In the example shown, diagnostic information collector 120 additionally has a corrected signature output 130 and a suspend output 132. Digital signature generator 122 additionally has a corrected signature input 131 connected to the corrected signature output 130 of diagnostic information collector 120. After generating fault indication FI in response to a fault-indicating representative signature, diagnostic information collector 120 outputs at corrected signature output 130 a corrected signature that is used in digital signature generator 122 to overwrite or otherwise replace at least part of the digital signature underlying the fault-indicating representative signature.

BIST controller 126 additionally has a suspend input 133 connected to the suspend output 132 of diagnostic information collector 120. After generating fault indication FI in response to a fault-indicating representative signature, diagnostic information collector 120 sets suspend output 132 to a state that causes BIST controller 126 to cause BIST 116 to suspend its normal testing operations while diagnostic information collector 120 outputs the diagnostic information to ATE 112. Causing BIST 116 to suspend its normal testing operations during the diagnostic information output operation reduces the storage needed to store the diagnostic patterns within diagnostic information collector 120.

Typically, the fault indication port 134 of diagnostic information collector 120 and the fault indication port 136 of ATE 112 are bidirectional. When the representative signature output by digital signature generator 122 is a fault-indicating representative signature, diagnostic information collector 120 provides fault indication FI at fault indication port 134. Fault indication FI received at fault indication port 136 causes ATE 112 to suspend performing the test routine and to perform the diagnostic information receiving routine instead. The diagnostic information receiving routine causes ATE 112 to receive the diagnostic information output by diagnostic information collector 120. To cause ATE 112 to execute the diagnostic information receiving routine, the main test routine executed by ATE 112 may periodically test the state of fault indication port 136 to determine whether fault indication FI is present. Alternatively, fault indication FI received at fault indication port 136 may act as an interrupt for ATE 112. In an embodiment, ATE 112 additionally signals its readiness to receive the diagnostic information from diagnostic information collector 120 by providing a ready signal to diagnostic information collector 120 via fault indication port 136, fault indication path 135 and fault indication port 134.

ATE 112 has an expected signature information output 139 connected via expected signature information path 138 to the expected signature information input 137 of diagnostic information collector 120. At least at the beginning of each test sequence, ATE 112 provides expected signature information to diagnostic information collector 120 via expected signature information link 138. In some embodiments, diagnostic information collector 120 uses the expected signature information itself as the expected signature corresponding to each representative signature output by digital signature generator 122. In other embodiments, diagnostic information collector 120 uses the expected signature information as a seed from which it generates the expected signature corresponding to each representative signature.

FIG. 2 is a block diagram showing an example of a diagnostic information collector 150 that may be used as diagnostic information collector 120 in logic device 110 described above with reference to FIG. 1. Diagnostic information collector 150 will be described with additional reference to FIG. 1.

Diagnostic information collector 150 has a comparator 142, a buffer 144, an expected signature source 152, a corrected signature generator 154 and a controller 156. Comparator 142 has a representative signature input, an expected signature input 143 and a comparison output 145. Buffer 144 has a bidirectional control port 146, a diagnostic pattern input and a diagnostic information output. Expected signature source 152 has an expected signature information input and an expected signature output 153. Corrected signature generator 154 has an expected signature input 157, a corrected signature output and a control input 159. Controller 156 has a bidirectional fault indication port, a corrected signature control output 163, a comparison input 165, a suspend output and a bidirectional buffer control port 169.

In expected signature source 152, the expected signature information input provides the expected signature information input 137 of diagnostic information collector 150 and is connected to expected signature information path 138. Expected signature output 153 is connected the expected signature input 143 of comparator 142 and to the expected signature input 157 of corrected signature generator 154. Expected signature output 153 provides to expected signature input 143 an expected signature ES corresponding to each representative signature received at the representative signature input 123 of comparator 142. As noted above, the expected signature can be the expected signature information itself or expected signature source 152 can derive the expected signature from the expected signature information.

The corrected signature output of corrected signature generator 154 provides the corrected signature output 130 of diagnostic information collector 150.

In controller 156, the fault indication port provides the fault indication port 134 of diagnostic information collector 150 and is connected to fault indication path 135. The suspend output provides the suspend output 132 of diagnostic information collector 150. Comparison input 165 is connected to the comparison output 145 of comparator 142. Buffer control port 169 is connected to the control port 146 of buffer 144.

In comparator 142, the representative signature input provides the representative signature input 123 of diagnostic information collector 150 and receives the representative signature output by digital signature generator 122 after each output shift operation performed by scan chains 24.

In buffer 144, the diagnostic pattern input provides the diagnostic pattern input 125 of diagnostic information collector 150 and is connected to diagnostic pattern bus 124. The diagnostic information output provides the diagnostic information output 127 of diagnostic information collector 150 and is connected to diagnostic pattern output path 128.

In operation, buffer 144 receives via diagnostic pattern input 125 a diagnostic pattern composed of the responses output by each output shift operation performed by scan chains 24. Buffer 144 additionally receives one or more buffer control signals from controller 156. In response to the buffer control signals, buffer 144 temporarily stores the newly-received diagnostic pattern in such a way that the newly-received diagnostic pattern replaces the oldest diagnostic pattern stored in the buffer. Typical replacement methods include overwriting the oldest diagnostic pattern with the newly-received diagnostic pattern and shifting the oldest diagnostic pattern out of the buffer as the newly-received diagnostic pattern is shifted into the buffer. By replacing the oldest diagnostic pattern with the newly-received diagnostic pattern, buffer 144 always temporarily stores the diagnostic patterns output by scan chains 24 in the N most-recently performed output shift operations, where N is less than the total number of output shift operations needed to shift out of the scan chains all of the responses captured from logic circuits 14 in response to a given stimulus vector. By storing only the diagnostic patterns output by scan chains 24 in what is typically a small subset of the total number of output shift operations, the size of buffer 144 can be relatively small. Minimizing the size of buffer 144 is highly desirable to prevent the incorporation of diagnostic information collector 120 from significantly increasing the die area and, hence, the cost of logic device 110. However, the number of diagnostic patterns stored in buffer 144 must be sufficient to ensure that, when diagnostic information collector 150 provides fault indication FI at fault indication port 134, the fault-indicating diagnostic pattern that caused such fault indication has not been replaced by a diagnostic pattern subsequently stored in buffer 144.

Additionally, when diagnostic information collector 150 detects a fault and ATE 112 indicates its readiness to receive diagnostic information from logic device under test 110, controller 156 provides a buffer control signal at buffer control port 169 in a state that causes buffer 144 to output to ATE 112 at least some of the diagnostic patterns stored therein. Buffer 144 outputs the stored diagnostic patterns via diagnostic information output 127 and diagnostic information path 128. Since the fault-indicating diagnostic pattern that caused the diagnostic patterns to be output from buffer 144 exists among the diagnostic patterns output from buffer 144, analysis of the diagnostic patterns output from buffer 144 will reveal the identity and failure mode of the faulty cell in logic circuits 14. The diagnostic patterns output from buffer 144 therefore constitute diagnostic information.

Comparator 142 receives via representative signature input 123 the representative signature output by digital signature generator 122 after each output shift operation performed by scan chains 24. Comparator 142 additionally receives at expected signature input 143 an expected signature ES corresponding to such representative signature. Comparator 142 compares the representative signature with the expected signature. When the representative signature differs from the expected signature, the comparison output 145 of comparator 142 changes from a normal state to a fault state.

Controller 156 operates in response to the state of the comparison output 145 of comparator 142 to control the operation of diagnostic information collector 150, BIST 116 and ATE 112. In response to the comparison output 145 of comparator 142 in its normal (non-fault) state, controller 156 provides to BIST controller 126 via suspend output 132 a suspend signal in a normal state. In its normal state, the suspend signal allows BIST controller 126 to enable BIST 116 perform the sequence of tests constituting the test sequence. Controller 156 additionally provides to corrected signature generator 154 an activation signal in a normal state. In its normal state, the activation signal inhibits the operation of corrected signal generator 156. Controller 156 additionally provides a fault indication signal to ATE 112 via flow control port 134. The fault indication signal is in a state that provides no fault indication. In response to the fault indication signal in the state that provides no fault indication, ATE 112 executes the main test routine. Finally, controller 156 provides to the control port 146 of buffer 144 one or more buffer control signals that cause the buffer to store the diagnostic patterns received at diagnostic pattern input 125 from diagnostic pattern bus 124 after each output shift operation performed by scan chains 24.

In response to the output 145 of comparator 142 changing to a fault state, controller 156 changes the suspend signal provided to BIST controller 126 to a suspend state. In its suspend state, the suspend signal causes BIST controller 126 to cause BIST 116 to suspend performing its normal testing operations on memory circuits 14. This temporarily stops scan chains 24 performing output shift operations.

Controller 156 additionally changes the fault indication signal provided to fault indication port 134 to a state that provides fault indication FI. In response to fault indication FI, ATE 112 executes a diagnostic information receiving routine that in part sets ATE 112 to a state in which it can receive the diagnostic information output by diagnostic information source 150. Typically, controller 156 waits for a ready signal sent by ATE 112 via fault indication port 134 before causing buffer 144 to output the diagnostic information. The ready signal indicates to controller 156 that ATE is ready to receive the diagnostic information. On receiving such ready signal, controller 156 provides to buffer 144 one or more buffer control signals that cause the buffer to output the diagnostic information to ATE 112. As noted above, buffer 144 outputs the diagnostic information to ATE 112 via diagnostic information output 127, diagnostic information path 128 and diagnostic information input 129.

Controller 156 additionally changes the activation signal provided to corrected signature generator 154 to an activate state. In its activate state, the activation signal causes corrected signature generator 154 to output a corrected signature and causes digital signature generator 122 to overwrite or otherwise replace the digital signature underlying the fault-indicating representative signature with the corrected digital signature received from corrected signature generator 154. Overwriting the digital signature underlying the fault-indicating representative signature restores the comparison output 145 of comparator 142 to its normal (non-fault) state.

Once the diagnostic information has been output from buffer 144, controller 156 restores the suspend, activation, fault indication and buffer control signals to their original states. This reactivates BIST 116, restores the flow of diagnostic patterns to diagnostic pattern input 125 and the storing of such diagnostic patterns in buffer 144, inhibits corrected signature generator 154, causes ATE 112 to resume execution of the main test routine, and resumes the operation of diagnostic information collector 150.

BIST 116 continues to test logic device under test 110 until it reaches the end of the test sequence. Concurrently with BIST 116 reaching the end of the test sequence, ATE 112 performs the test result segment of the main test routine in which it receives a test result from logic device under test 110 via test result port 33 or otherwise determines a test result for logic device under test 110. The test result segment evaluates the test result to categorize logic device under test 110 as good or bad.

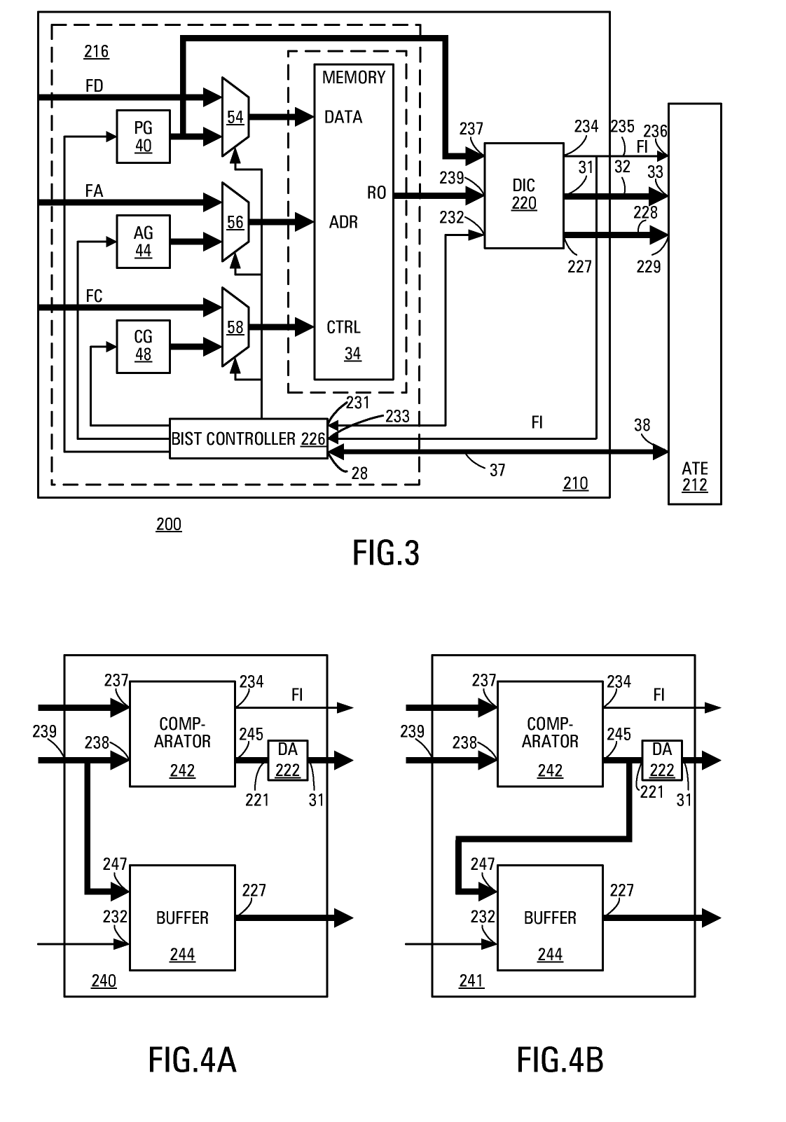

FIG. 3 is a block diagram showing an example of a system 200 comprising a memory device under test 210 and an example of automatic test equipment 212 in accordance with an embodiment of the invention that receives diagnostic information output from the memory device under test.

Memory device 210 comprises a memory circuit 34, a built-in self-test system (BIST) 216 and a diagnostic information collector (DIC) 220. BIST 216 performs a sequence of tests to test memory circuit 34. When BIST 216 reads an output pattern that indicates a fault in memory circuit 34, memory device under test 210 provides diagnostic information for output to ATE 212. Since BIST 216 can detect a fault at any point in the test sequence, ATE 212 is structured to behave non-deterministically to enable it to receive the output diagnostic information.

The example of BIST 216 shown in FIG. 3 is composed of a pattern generator (PG) 40, an address generator (AG) 44, a control signal generator (CG) 48 and multiplexers 54, 56, and 58. Each multiplexer 54, 56 and 58 has two inputs and an output. Pattern generator 40, address generator 44 and control signal generator 48 are connected to one input of multiplexers 54, 56 and 58, respectively. The functional data input FD, the functional address input FA and the functional control input FC of memory device 210 are connected to the other input of multiplexers 54, 56 and 58, respectively. Functional data input FD, functional address input FA and functional control input FC of memory device 210 are the inputs used for data, addresses and control signals, respectively, during in-service operation of memory device 210, i.e., during operation of memory device 210 except when it is being tested using BIST 216. The data input (DATA), address input (ADR) and control input (CTRL) of memory circuit 34 are connected to the outputs of multiplexers 54, 56 and 58, respectively.

During in-service operation of memory device 210, multiplexers 54, 56 and 58 connect the functional data input FD, the functional address input FA and the functional control input FC, respectively, of memory device 210 to the data input (DATA), address input (ADR) and control input (CTRL), respectively, of memory circuit 34.

BIST 216 additionally comprises a BIST controller 226 that communicates with ATE 212 via a control port 28, a control port 38 and a control path 37. BIST controller 226 generates control signals that control the operation of pattern generator 40, address generator 44, control signal generator 48, multiplexers 54, 56 and 58 and diagnostic information collector 220. During testing of memory device 210, the control signals output by BIST controller 226 cause multiplexers 54, 56 and 58 to connect the outputs of pattern generator 40, address generator 44, control signal generator 48, respectively, to the data input (DATA), address input (ADR) and control input (CTRL), respectively, of memory circuit 34. Control signals output by BIST controller 226 additionally cause pattern generator 40, address generator 44, control signal generator 48 to generate the test patterns and expected patterns, the addresses and the WRITE and READ commands, respectively, used to test memory device 210, specifically, memory circuit 34. Additionally, BIST controller 226 exchanges control signals with the control port 38 of ATE 212 via control port 28 and control path 37. BIST controller 226 additionally has a control port 231 and a fault-indication input 233.

Diagnostic information collector 220 has an expected pattern input 237 and an output pattern input 239. Output pattern input 239 is connected to the read output (RO) of memory circuit 34 from which it receives the output patterns read from the memory locations of memory circuit 34 defined by the addresses generated by address generator 44 and in response to the control signals generated by control signal generator 48. Expected pattern input 237 is connected to the output of pattern generator 40 from which it receives a corresponding expected pattern corresponding to each output pattern received at output pattern input 239. Each corresponding expected pattern is identical to the test pattern written at the memory location of memory circuit 34 from which the output pattern was read.

Diagnostic information collector 220 additionally has a fault indication output 234, a control port 232, a diagnostic information output 227 and a test result output 31. Fault indication output 234 is internally coupled to the fault indication input 233 of BIST controller 226. Control port 232 is internally coupled to the control port 231 of BIST controller 226.

Diagnostic information collector 220 includes the above-mentioned test result output 31 and generates a test result that is output at test result output 31 to provide compatibility with conventional memory test routines executed by ATE 212. Test result output 31 and its associated difference accumulator 222 (described below with reference to FIG. 4A) may be omitted from diagnostic information collector 220 in versions of memory device 210 intended to be tested by an embodiment of ATE 212 that executes a modified memory test routine having a test result segment capable of determining a test result for memory device under test 210 without the ATE receiving a test result from the memory device under test itself. For example, the ATE can determine a test result for the memory device under test by determining whether it received fault indication FI or whether it received diagnostic information while it was testing the memory device under test.

Diagnostic information collector 220 temporarily stores diagnostic patterns corresponding to the output patterns read from memory circuit 34. In one embodiment, the diagnostic information collector stores the output patterns received from memory circuit 34 at output pattern input 239 as corresponding diagnostic patterns. In another embodiment, the diagnostic information collector stores difference patterns as corresponding diagnostic patterns. Each difference pattern represents a respective difference between the output pattern received from memory circuit 34 at output pattern input 239 and the corresponding expected pattern received from pattern generator 40 at expected pattern input 237.

Diagnostic information collector 220 additionally compares each output pattern with its corresponding expected pattern to detect any difference between the output pattern and the corresponding expected pattern. A difference between the output pattern and its corresponding expected pattern causes diagnostic information collector 220 to provide fault indication FI at fault indication output 234. Otherwise, diagnostic information collector 220 provides no fault indication at fault indication output 234.

During operation of BIST 216 to test memory device under test 210, in response to control signals generated by BIST controller 226 in response to a start testing command received from ATE 212 at control input 28, control signal generator 48 generates a control signal that sets memory circuit 34 to its write mode, address generator 44 generates an address signal that defines a memory location in memory circuit 34 and pattern generator 40 generates a test pattern that is written at the memory location in memory circuit 34. In response to further control signals provided by BIST controller 226, address generator 44 generates an address signal that again defines the memory location in memory circuit 34 at which the test pattern was written, control signal generator 48 generates a control signal that sets memory circuit 34 to its read mode, and memory circuit 34 reads a respective output pattern from the memory location defined by the address signal. The output pattern is received by diagnostic information collector 220 at output pattern input 239. Additionally, pattern generator 40 generates an expected pattern identical to the test pattern that was written at the memory location and outputs the expected pattern as the expected pattern corresponding to the output pattern to the expected pattern input 237 of diagnostic information collector 220.

Diagnostic information collector 220 temporarily stores a diagnostic pattern corresponding to each output pattern such that the diagnostic patterns corresponding to no more than a most-recently read subset of the output patterns are stored. The most-recently read subset of the output patterns is composed of output patterns read from fewer than all the memory locations in memory device 210, i.e., in memory circuit 34. In one embodiment, the output pattern received at output pattern input 239 is stored as the diagnostic pattern corresponding to the output pattern. In another embodiment, the difference pattern representing the difference between the output pattern received at output pattern input 239 and the corresponding expected pattern received at expected pattern input 237 is stored as the corresponding diagnostic pattern corresponding to the output pattern. No difference, as occurs when the output pattern and its corresponding expected pattern are identical, is regarded herein as being a special case of a difference.

In the event that diagnostic pattern storage within diagnostic information collector 220 becomes full, the diagnostic information collector provides a control signal at control port 232. Received at the control port 231 of BIST controller 226, the control signal instructs BIST controller 226 to command BIST 216 to suspend its normal testing operations until the stored diagnostic patterns can be output.

Diagnostic information collector 220 additionally compares the output pattern read from the memory location and received at output pattern 239 with the corresponding expected pattern received at expected pattern input 237, and provides fault indication FI at fault indication output 234 when the output pattern differs from the corresponding expected pattern.

Finally, diagnostic information collector 220 generates a cumulative difference that, at the end of the test sequence performed by BIST 226, it outputs at a test result output 31 as the test result for memory device under test 210.

ATE 212 has a test result input 33, control port 38, a diagnostic information input 229 and a fault indication port 236. A test result path 32 connects test result input 33 to the test result output 31 of diagnostic information collector 220. The test result path and test result input may be omitted in an embodiment of ATE 212 capable of determining a test result for memory device under test 210 without receiving a test result from the memory device under test itself.

BIST controller 226 controls the operation of BIST 216 in response to control signals provided by ATE 212 via control path 37 and additionally provides status information to ATE 212 via control path 37. A diagnostic information path 228 connects diagnostic information input 229 to the diagnostic information output 227 of diagnostic information collector 220. A fault indication path 235 connects fault indication port 236 to the fault indication port 234 of diagnostic information collector 220.

In operation to test memory device under test 210, ATE 212 executes a main test routine that causes ATE 212 to perform conventional testing operations. Near the beginning of the main test routine, ATE 212 provides control signals to BIST controller 226 via control path 37. The control signals cause BIST controller 226 to initialize BIST 216 and command BIST 216 to perform a sequence of tests to test the memory circuit 34 of memory device under test 210. As BIST 216 performs the sequence of tests, the main test routine executed by ATE 212 causes the ATE to perform other testing operations. At the end of the sequence of tests, diagnostic information collector 220 generates the cumulative difference that provides a test result for memory device under test 210. Diagnostic information collector outputs the test result to the test result input 33 of ATE 212 via test result path 32. The main test routine performed by ATE 212 includes a test result segment that is performed concurrently with the end of the test sequence executed by BIST 216. The test result segment causes ATE 212 to receive the test result from memory device under test 210 at test result input 33 or causes ATE 212 otherwise to determine a test result for memory device under test 210. The test result segment evaluates the test result to categorize memory device under test 210 as good or bad and to provide an output indicating the category of memory device under test 210.

When ATE 212 tests a fault-free example of memory device under test 210, each output pattern is identical to its corresponding expected pattern so that BIST 216 reaches the end of the test sequence without diagnostic information collector 220 generating fault indication FI. Concurrently with the end of the test sequence performed by BIST 216, ATE 212 executes the above-described test result segment of the main test routine to receive the test result provided by diagnostic information collector 220 or otherwise to determine a test result for memory device under test 210. The test result segment additionally evaluates the test result to categorize memory device under test 210 as good or bad. In this example, the evaluation of the test result categorizes memory device under test 210 as good.

Diagnostic information collector 220 includes test result output 31 to provide compatibility with conventional memory test routines executed by ATE 212. Alternatively, the test result segment of the main test routine executed by ATE 212 may be modified to allow ATE 212 to determine a test result for memory device under test 210 without receiving a test result from the memory device under test itself. For example, the test result segment may be modified to determine a test result for memory device under test 210 based on whether ATE 212 received fault indication FI or received diagnostic information while it was testing the memory device under test. This allows test result output 31 and its associated difference accumulator 222 described below with reference to FIG. 4A to be omitted from memory device 210.

When ATE 212 tests an example of memory device under test 210 having at least one fault, at least one output pattern differs from its corresponding expected pattern, and, for each differing output pattern, diagnostic information collector 220 provides fault indication FI and outputs at least some of the stored diagnostic patterns to ATE 212 as diagnostic information. Diagnostic information collector 220 outputs the diagnostic patterns at diagnostic information output 227 connected to the diagnostic information input 229 of ATE 212 by diagnostic information path 228. In an embodiment, fault indication FI at the fault indication output 234 of diagnostic information collector 220 causes BIST controller 226 to provide control signals at control output 231. Such control signals are received at the control input 232 of diagnostic information collector 220 and cause diagnostic information collector 220 to output the stored diagnostic patterns. Fault indication FI provided at fault indication output 234 additionally indicates to ATE 212 that diagnostic information collector 220 has detected a fault. In response to fault indication FI, ATE 212 performs a diagnostic information receiving routine that sets ATE 212 to receive the diagnostic information output from diagnostic information collector 220.

The diagnostic information output to ATE 212 indicates the nature of the fault, i.e., the erroneous output pattern, but does not identify the location of the fault, i.e., the address of the faulty memory location. Location information can be provided in two ways. In a first way of providing location information, BIST controller 226 keeps track of the address of the memory location under test as it tests memory device 210. Consequently, as part of the process of receiving the diagnostic information, the ATE can provide a control signal via control path 37 to request BIST controller 226 to output via control path 37 the address of the memory location under test. The address of the current memory location provides the location information or can be used by ATE 212 to determine the location information. This way of providing location information requires that no storage be provided for location information in diagnostic information collector 220, but requires that BIST 216 suspend its normal testing operations immediately in response to fault indication FI.

In a second way of providing location information, diagnostic information collector 220 has an additional input (not shown) connected to the output of address generator 44. The additional input receives from address generator 44 the address of the memory location from which the output pattern received at output pattern input 239 was read. In such an embodiment, each diagnostic pattern is composed of the diagnostic pattern as described above, i.e., the output pattern or the difference pattern, concatenated with the address received from address generator 44. The address that forms part of each diagnostic pattern provides the location information that allows the defective memory cell to be identified. This way of providing location information requires that storage be provided in diagnostic information collector 220 for the location information that additionally constitutes part of the stored diagnostic patterns, but does not require that BIST 216 suspend its normal testing operations in response to fault indication FI.

FIG. 4A is a block diagram showing an example of an embodiment 240 of a diagnostic information collector that may be used as diagnostic information collector 220 in memory device 210 described above with reference to FIG. 3. Diagnostic information collector 240 will be described with additional reference to FIG. 3. Diagnostic information collector 240 comprises a comparator 242, a buffer 244 and a difference accumulator (DA) 222. In this embodiment, buffer 244 stores each output pattern received at output pattern input 239 as the diagnostic pattern corresponding to the output pattern.

Comparator 242 has an expected pattern input, an output pattern input 238, a difference pattern output 245 and a fault indication output. The expected pattern input and fault indication output of comparator 242 provide the expected pattern input 237 and fault indication output 234, respectively, of diagnostic information collector 220. Output pattern input 238 is connected to the output pattern input 239 of diagnostic information collector 240.

In operation of comparator 242, expected pattern input 237 receives the corresponding expected pattern output by pattern generator 40 during each read operation performed by memory circuit 34. Output pattern input 238 receives from the output pattern input 239 of diagnostic information collector 220 the output pattern read from memory circuit 34 by each read operation. Comparator 242 compares each output pattern with the corresponding expected pattern to generate a corresponding fault indication signal that it outputs at fault indication output 234, and additionally to generate a difference pattern that it outputs at difference output 245.

The difference pattern generated by comparator 242 provides a bit-by-bit indication of the modulus of any difference between the output pattern and its corresponding expected pattern. Typically, the output pattern is identical to the corresponding expected pattern. In this case, the comparison performed by comparator 242 provides the fault indication signal in a state that provides no fault indication, and the difference pattern output by comparator 242 has a logical zero in every bit position. When the output pattern differs from the corresponding expected pattern, the comparison performed by comparator 242 generates the fault indication signal in a state that provides fault indication FI. Additionally, the difference pattern output by comparator 242 has a logical one at each bit position where the output pattern differs from the corresponding expected pattern and has a logical zero at each remaining bit position. The logical ones and logical zeroes may be interchanged.

Difference accumulator 222 has a difference pattern input 221 and a test result output. Difference pattern input 221 is connected to the difference pattern output 245 of comparator 242. The test result output of difference accumulator 222 provides the test result output 31 of diagnostic information collector 220. In operation, difference accumulator 222 accumulates the difference patterns output by comparator 242 so that at the end of the test sequence performed by BIST 216, the test result output 31 of the difference accumulator has a logical one at every bit position where one of the output patterns has differed from its corresponding expected pattern. As noted above, difference accumulator 222 and test result output 31 may be omitted from embodiments of memory device 210 intended for testing by an embodiment of ATE 212 capable of determining a test result for the memory device under test without receiving a test result provided by the memory device under test itself.

Buffer 244 has a control port, a diagnostic pattern input 247 and a diagnostic pattern output. The control port and diagnostic pattern output of buffer 244 provide the control port 232 and diagnostic pattern output 227 of diagnostic information collector 240. In the example shown in FIG. 4A, diagnostic pattern input 247 is connected to the output pattern input 239 of diagnostic information collector 240 and receives each output pattern received at output pattern input 239 as the diagnostic pattern corresponding to the output pattern.

An embodiment of buffer 244 that additionally stores a respective address as part of each diagnostic pattern additionally has an address input (not shown) connected to the output of address generator 44. The width of such an embodiment of buffer 244 is greater than that of an embodiment in which the diagnostic patterns lack respective addresses. The increase in width is equal to the width of the addresses.

In operation, the example of buffer 244 shown in FIG. 4A receives via diagnostic pattern input 247 the output pattern read from memory circuit 34 by each read operation as a respective diagnostic pattern. Buffer 244 additionally receives via control input 232 one or more control signals from BIST controller 226. In response to the control signals, buffer 244 temporarily stores each diagnostic pattern received at diagnostic pattern input 247.

Buffer 244 stores each newly-received diagnostic pattern in such a way that the newly-received diagnostic pattern replaces the oldest diagnostic pattern stored in the buffer. Typical replacement methods include overwriting the oldest diagnostic pattern stored in the buffer with the newly-received diagnostic pattern and shifting the oldest diagnostic pattern out of the buffer as the newly-received diagnostic pattern is shifted into the buffer. By replacing the oldest diagnostic pattern with the newly-received diagnostic pattern, buffer 244 always temporarily stores the diagnostic patterns corresponding to the N most-recently performed read operations, where N is less than the total number of read operations needed to read all of the memory locations in memory circuit 34. By storing only the diagnostic patterns corresponding to the output patterns read in what is typically a small subset of the total number of read operations performed to read all the memory locations in memory circuit 14, the size of buffer 244 can be relatively small. Minimizing the size of buffer 244 is highly desirable to prevent the incorporation of diagnostic information collector 220 from significantly increasing the die size and, hence, the cost of device under test 210. However, the number of diagnostic patterns stored in buffer 244 must be sufficient to ensure that, when comparator 242 provides fault indication FI, the fault-indicating diagnostic pattern corresponding to the fault-indicating output pattern that caused comparator 242 to provide fault indication FI has not been replaced by a diagnostic pattern subsequently stored in buffer 244, as discussed above. The number of diagnostic patterns stored depends in part on whether and how BIST 216 suspends its normal testing operations in response to fault indication FI.

In other embodiments, the diagnostic patterns are successively presented to the diagnostic pattern input 247 of buffer 244 but buffer 244 does not store them. Only when fault indication FI is additionally provided to buffer 244 does the buffer store the diagnostic patterns received at diagnostic pattern input 247.

FIG. 4B is a block diagram showing another example of a diagnostic information collector 241 that may be used as diagnostic information collector 220 in memory device 210 described above with reference to FIG. 3. Diagnostic information collector 241 will be described with additional reference to FIG. 3. Diagnostic information collector 241 comprises comparator 242, buffer 244 and difference accumulator 222. In this embodiment, the difference pattern generated by comparator 242 from each output pattern received at output pattern input 239 and its corresponding expected pattern received at expected pattern input 237 is stored by buffer 244 as the diagnostic pattern corresponding to the output pattern received at output pattern input 239.

The structure and operation of comparator 242, buffer 244 and difference accumulator 222 are identical to those of the corresponding elements of diagnostic information collector 240 described above with reference to FIG. 4A. However, in diagnostic information collector 241, the diagnostic pattern input 247 of buffer 244 is connected to the difference pattern output 245 of comparator 242. Consequently, in diagnostic information collector 241, each diagnostic pattern stored in buffer 244 is a difference pattern generated by comparator 242 from an output pattern read from memory circuit 34 and its corresponding expected pattern.

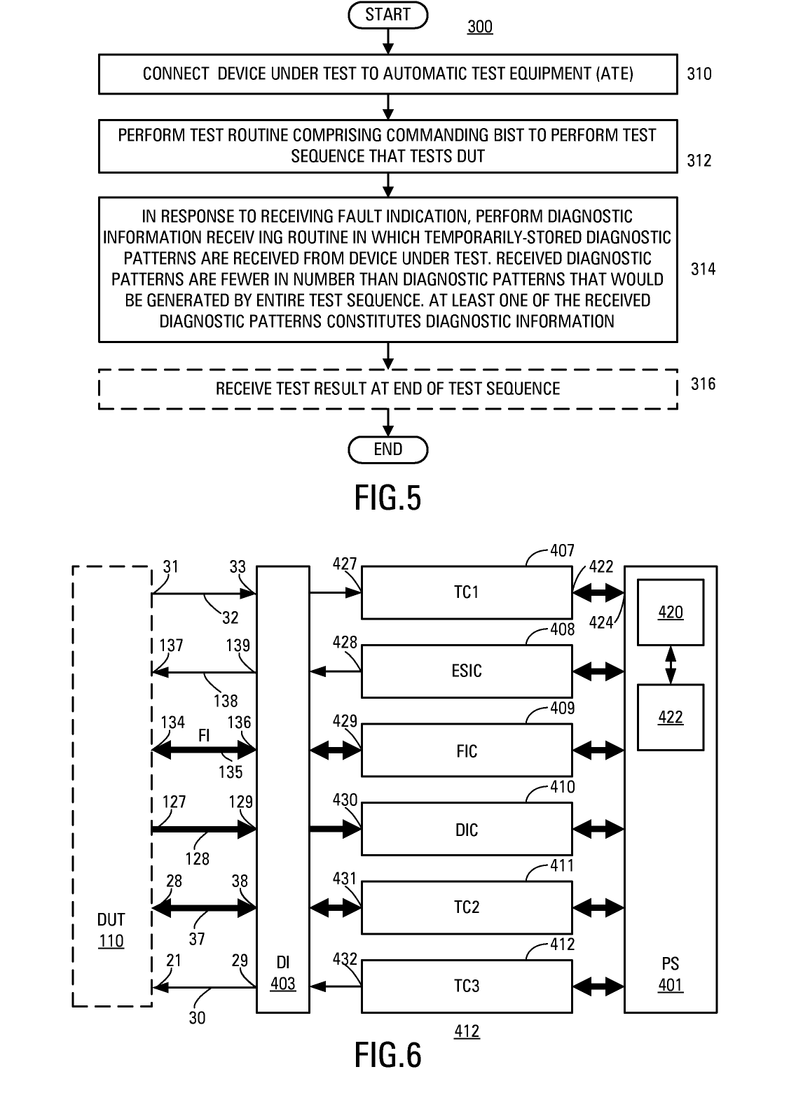

FIG. 5 is a flow chart showing an example of a method 300 in accordance with an embodiment of the invention for operating ATE 112 or ATE 212 to obtain diagnostic information from a device under test having a built-in self-test system (BIST) and a diagnostic information collector. The BIST performs a sequence of tests to test the device under test. The diagnostic information collector provides a fault indication when an output pattern received from the BIST indicates a fault, and additionally temporarily stores diagnostic patterns.

In block 310, the device under test is connected to the ATE. In block 312, the ATE performs a main test routine. The main test routine comprises such operations as commanding the BIST to perform a test sequence that tests the device under test. Optionally, the main test routine additionally comprises receiving a test result for the device under test at the end of the test sequence, as indicated by block 316. Such test result, if received by the ATE, does not provide diagnostic information.

In block 314, the ATE performs a diagnostic information receiving routine in response to receiving the above-mentioned fault indication. The ATE receives the fault indication at an arbitrary point in the test sequence, depending on where in the test sequence the fault-indicating output pattern is generated. In the diagnostic information receiving routine, the ATE receives diagnostic patterns from the device under test. The diagnostic patterns received are fewer in number than the diagnostic patterns that would be generated by the entire test sequence. At least one of the received diagnostic patterns constitutes diagnostic information. After the diagnostic information receiving routine has executed, execution of the main test routine resumes until testing of the device under test is complete. As noted above, the main test routine may additionally comprise block 316 in which the ATE receives a test result for the device under test at the end of the test sequence.

FIG. 6 is a block diagram showing an example of ATE 412 in accordance with an embodiment of the invention for receiving diagnostic information from a device under test. The example of ATE 412 shown can be used as ATE 112 described above with reference to FIG. 1 to test logic devices each having a built-in self-test system and a diagnostic information collector. A somewhat simplified version of ATE 412 may be used as ATE 212 described above with reference to FIG. 3 to test memory devices each having built-in self-test system and a diagnostic information collector.

The example of ATE 412 has a processing system (PS) 401, a device interface (DI) 403, and a number of processing channels 407-412 connected to processing system 401 and to device interface 403. The number of processing channels may be more than or fewer than the number illustrated.

Device interface 403 is structured to provide connections to logic device under test 110. In an embodiment, device interface 403 has a socket into which a packaged device under test 110 is plugged for final test. In another embodiment, suitable for testing the device under test before it is packaged, device interface 403 has probes and a mechanism that brings the probes into contact with pads on the die of a wafer in which multiple devices under test have been fabricated.

Referring additionally to FIG. 1, device interface 403 provides the following elements of ATE 112: test result input 33, expected signature information output 139, fault indication port 136, diagnostic information input 129, control port 38 and seed output 29. When logic device under test 110 is connected to ATE 112 via device interface 403, test result input 33 is connected to the test result output 31 of logic device under test 110, expected signature information output 139 is connected to the expected signature information input 137 of diagnostic information collector 120, fault indication port 136 is connected to the fault indication port 134 of diagnostic information collector 120, diagnostic information input 129 is connected to the diagnostic information output 127 of diagnostic information collector 120, control port 38 is connected to the control port 28 of BIST controller 126 and seed output 29 is connected to the seed input 21 of stimulus generator 20.

Each of the processing channels 407-412 provides a respective communication path between device interface 403 and processing system 401. Typically, each of the processing channels 407-412 comprises either or both of an input circuit and an output circuit via which the processing channel receives a signal and/or data from, or provides a signal and/or data to, part of device under test 110. Some of the processing channels have multiple input circuits or output circuits. For example, processing channel 409 has an input circuit (not shown) via which it receives fault indication FI from the fault indication port 134 of device under test 110 and an output circuit (not shown) via which it provides a ready signal to the fault indication port 134 of device under test 110. In another example in which the diagnostic patterns output by device under test 110 are eight-bit words output in parallel, processing channel 410 comprises eight input circuits, one for each bit of the diagnostic patterns. Such input circuits and output circuits will be referred to generically as I/O circuits. At least some of the processing channels additionally have a data processing capability.

Processing channels 407, 411 and 412 are identified as testing channels (TC1-TC3). Such channels are similar to those found in conventional ATE for testing conventional logic devices each having a BIST but no diagnostic information collector.

Processing channels 408, 409 and 410 are specific to ATE 412 in accordance with an embodiment of the invention: processing channel 408 is an expected signature information channel (ESIC) that provides expected signature information to expected signature information input 137; processing channel 409 is a fault indication channel (FIC) that receives fault indication FI from, and provides a ready signal to, fault indication port 134; and processing channel is a diagnostic information channel (DIC) that receives the diagnostic information from diagnostic information output 127.

Processing system 401 typically comprises a processor 420, a memory 422, an input circuit and/or an output circuit (not shown), and other components. Additional processors and memory may constitute part of one or more of processing channels 407-412. In processing system 401, processor 420 executes a main test routine that causes test channels 407, 411 and 412 to send and receive signals and data that enable BIST 116 to test logic device 110. Processor 420 additionally operates in response to fault indication FI received via fault indication channel 409 to execute a diagnostic information receiving routine that enables ATE 412 to receive diagnostic information from logic device 110 via diagnostic information channel 410. Test channel 407 is omitted in some embodiments, as will be described below.

Each of processing channels 407-412 has a port connected to a corresponding port on processing system 401 via which the processing channel exchanges data and control signals with processing system 401. For example, processing channel 407 has a port 422 connected to a port 424 of processing system 401. The other processing channels are similar. Each of processing channels 407-412 is additionally connected to device interface 403. Test channel 407 has a test result input 427 connected to test result input 33; expected signature information channel 408 has an expected signature information output 428 connected to expected signature information output 139; fault indication channel 409 has a fault indication port 429 connected to fault indication port 136; diagnostic information channel 410 has a diagnostic information input 430 connected to diagnostic information input 129; test channel 411 has a control port 431 connected to control port 38; and test channel 412 has a seed output 432 connected to seed output 29. The above-described inputs, outputs and ports of processing channels 407-411 are connected to the respective inputs, output and ports of ATE 412 via device interface 403.

Test channel 407 comprises an input circuit (not shown) having an input connected to test result input 427 via which test channel 407 receives from logic device under test 110 the test result output by digital signature generator 122 at the end of the test sequence performed by BIST 116. Test channel 407 is additionally connected to receive from processing system 401 a reference digital signature and a test result command generated by the test result segment of the main test routine executed by processing system 401. Processing system provides the test result command concurrently with the end of the test sequence performed by BIST 116 to test logic device under test 110.

Test channel 407 additionally includes a comparator (not shown) operable in response to the test result command to evaluate the test result for logic device under test 110. The comparator performs a comparison between the test result received from logic device under test 110 via test result input 427 and the reference digital signature and outputs the comparison result to processing system 401.

Processing system 401 categorizes logic device under test 110 as good when the comparison result indicates no difference between the test result and the reference digital signature. Processing system 401 categorizes logic device under test as bad when the comparison result indicates a difference between the test result and the reference digital signature. Alternatively, test channel 407 comprises a processor (not shown) that categorizes logic device under test 110 as good or bad and outputs the category of logic device under test 110 to processing system 401.

Expected signature information channel 408 comprises an output circuit (not shown) having an output connected to expected signature information output 428 via which expected signature information channel 408 provides expected signature information to the expected signature information output 139 of ATE 412 and thence to the expected signature information input 137 of logic device under test 110. Expected signature information channel 408 additionally comprises an on-board processor (not shown) and on-board memory (not shown) that operate in response to a program (not shown).

In an embodiment of expected signature information channel 408 for use in testing an embodiment of logic device 110 in which expected signature source 152 (FIG. 2) comprises a state machine (not shown) that generates an expected signature corresponding to each representative signature output by digital signature generator 122 (FIG. 1), the on-board processor operates before ATE 412 is used to test logic devices under test to store expected signature information in the on-board memory. The expected signature information acts as a seed for the state machine. Then, in response to the program and a start of test command issued by the main test routine executed by processing system 401, the on-board processor operates to read the stored expected signature information and to output the expected signature information to the expected signature source via the output circuit and expected signature information output 428. In response to the expected signature information, the state machine in expected signature source 152 generates an expected signature corresponding to each representative signature output by digital signature generator 122.

In an embodiment of expected signature information channel 408 for use in testing an embodiment of logic device 110 in which expected signature source 152 (FIG. 2) comprises a pass-through connection for each bit of the expected signature corresponding to each representative signature output by digital signature generator 122, the on-board processor and on-board memory operate in response to the start of test command to generate and output via expected signature information output 428 respective single-bit or multi-bit expected signature information that provides the expected signature corresponding to each representative signature output by digital signature generator 122.

Fault indication channel 409 comprises an input circuit (not shown) having an input connected to fault indication port 429 and fault indication port 136 via which ATE 412 receives fault indication FI output by the diagnostic information collector 120 of logic device under test 110. In some embodiments of ATE 412, the main test routine executed by processing system 401 includes repetitively-performed instructions that cause processing system 401 to test the input circuit for the presence of the fault indication. Detecting the presence of the fault indication at the input circuit of fault indication channel 409 causes processing system 401 to suspend execution of the main test routine and to execute the diagnostic information receiving routine instead. The diagnostic information receiving routine causes ATE 412 to receive the diagnostic information output by logic device under test 110. In other embodiments, processing system 401 has an interrupt input (not shown) coupled to the input circuit of fault indication channel 409, and the main test routine executed by processing system 401 comprises instructions that allow an interrupt received at the interrupt input of the processing system to force processing system 401 to suspend execution of the main test routine and to execute a diagnostic information receiving routine instead.

In some embodiments, fault indication channel 409 additionally comprises an output circuit (not shown) via which processing system 401 can provide a ready signal to fault indication port 429 and thence to the fault indication port 134 of device under test 110. The ready signal is generated by processing system 401 and indicates to logic device under test 110 that ATE 412 is ready to receive the diagnostic information temporarily stored in logic device under test 110. Fault indication channel 409 may additionally comprise additional input circuits and/or output circuits that pass other signals related to the output of the diagnostic information to and from logic device under test 110.

Diagnostic information channel 410 comprises an input circuit (not shown) via which it receives the diagnostic information output by logic device under test 110 at diagnostic information output 127 and received by ATE 412 at diagnostic information input 129. In some embodiments, the input circuit forwards the diagnostic information it receives to processing system 401. In such embodiments, processing system 401 controls the onward transmission and/or the storage of the diagnostic information received from the input circuit. In other embodiments, diagnostic information channel 410 comprises an on-board processor and on-board memory (not shown) coupled to the input circuit and that operate in response to a program (not shown). The on-board processor operates in response to a store command issued by the diagnostic information receiving routine executed by processing system 401 to cache the diagnostic information received from the input circuit in the on-board memory of diagnostic information channel 410 for later retrieval. In embodiments in which logic device under test 110 outputs the diagnostic information as a serial bitstream, processing channel 410 additionally comprises a demultiplexer (not shown) that demultiplexes the serial bitstream into multi-bit parallel words. Alternatively, diagnostic information channel 410 handles the diagnostic information as a serial bit stream, in which case, no demultiplexer is needed.

Fault indication channel 409 is described above as comprising additional input circuits and/or output circuits that exchange with logic device under test 110 control signals relating to the output of the diagnostic information. Such additional input circuits and/or output circuits may be located in diagnostic information channel 410 in addition to or instead of in fault indication channel 409.

Test channel 411 comprises input circuits and output circuits (not shown) whose inputs and outputs, respectively, are connected to control port 431 and thence to the control port 28 of the BIST controller 126 of logic device under test 110. The main test routine performed by processing system 401 uses such input circuits and output circuits to exchange control signals and status signals with the BIST controller 126 of logic device under test 110.

Test channel 412 comprises an output circuit (not shown) whose output is connected to seed output port 432 and thence via seed output 29 to the seed input 21 of the stimulus generator 20 of logic device under test 110. ATE 412 uses such output circuit to provide one or more seeds to stimulus generator 20. In some embodiments, test channel 412 additionally comprises an on-board processor (not shown) and on-board memory (not shown) coupled to the output circuit and that operate in response to a program and commands issued by the main test routine performed by processing system 401 to generate the seeds that are output to the logic device under test.

The operation of ATE 412 to test logic device under test 110 and, in the event that a fault is detected in logic device under test 110, to receive diagnostic information from logic device under test 110, will now be described with reference to FIGS. 1, 2 and 6.

Processing system 401 instructs test channel 411 to output a seed to seed output 29.

In an embodiment of logic device under test 110 in which expected signature source 152 generates the expected signature corresponding to each representative signature output by digital signature generator 122, the start of test command issued by the main test routine performed by processing system 401 instructs expected signature information channel 408 to output expected signature information to expected signature information output 139. Expected signature source 152 then operates in response to the expected signature information to generate an expected signature corresponding to each representative signature. The start of test command issued by the main test routine executed by processing system 401 additionally instructs test channel 411 to instruct BIST controller 126 to begin testing logic device under test 110.

In an embodiment of logic device under test 110 in which expected signature source 152 receives from expected signature information channel 408 expected signature information comprising the expected signature corresponding to each representative signature output by digital signature generator 122, the start of test command issued by the main test routine performed by processing system 401 instructs expected signature information channel 408 to begin generating the expected signature as expected signature information and to output the expected signature for each representative signature to expected signature information output 139.

In logic device under test 110, BIST 116 generates a digital signature in response to the diagnostic patterns after each output shift operation performed by scan chains 24 and outputs at least part of the digital signature to diagnostic information collector 120 as a respective representative signature. Diagnostic information collector 120 compares each representative signature with its corresponding expected signature. Additionally, diagnostic information collector 120 temporarily stores the diagnostic pattern output by each output shift operation performed by the scan chains.

Unless diagnostic information collector 120 detects a difference between the representative signature and the corresponding expected signature, BIST 116 continues to test logic circuits 14 until it reaches the end of the test sequence. Concurrently with BIST 116 reaching the end of the test sequence, the main test routine executed by processing system 401 reaches its test result segment that causes processing system 401 to supply the test result command to test channel 407. In response to the test result command, test channel 407 receives the test result from logic device under test 110 and evaluates the test result by comparing the test result with a reference digital signature. Test channel 407 outputs the resulting category for logic device under test 110 to processing system 401. In this example, logic device under test 110 is categorized as good.

A difference between any output pattern, i.e., representative signature, output by digital signature generator 122 and its corresponding expected signature causes diagnostic information collector 120 to generate fault indication FI and to output the fault indication at fault indication port 134. The fault indication is received from fault indication port 136 of ATE 412 by the fault indication port 429 of fault indication channel 409. In an embodiment of ATE 412 in which the main test routine executed by processing system 401 repetitively tests for the presence of fault indication FI at fault indication channel 409, the presence of fault indication FI causes processing system 401 to execute the diagnostic information receiving routine. In an embodiment of ATE 412 in which the fault indication FI received via fault indication channel 409 acts as an interrupt, fault indication FI immediately causes processing system 401 to execute the diagnostic information receiving routine. During execution of the diagnostic information receiving routine, execution of the main test routine is suspended.

The diagnostic information receiving routine executed by processing system 401 sets diagnostic information channel 410 to a state in which it can receive the diagnostic information output by logic device under test 110. Diagnostic information channel 410 notifies processing system 401 once it is ready to receive the diagnostic information, and, in response, processing system 401 provides a ready signal to fault indication channel 409. Fault indication channel 409 outputs the ready signal to logic device under test 110 via fault indication ports 429, 136 and 134.

In response to the ready signal received via fault indication port 134, diagnostic information collector 120 outputs to diagnostic information channel 410 the diagnostic information temporarily stored in buffer 144 via diagnostic information output 127, diagnostic information input 129 and diagnostic information input 430. Diagnostic information channel 410 caches the received diagnostic information in its on-board memory, or outputs the received diagnostic information to processing system 401.

Once diagnostic information collector 120 has finished outputting the temporarily-stored diagnostic information, it discontinues fault indication FI. Fault indication channel 409 receives the discontinuation of the fault indication via fault indication ports 136 and 429 and forwards such discontinuation to processing system 401. The discontinuation of the fault indication causes processing system 401 to halt execution of the diagnostic information receiving routine and to resume execution of the main test routine. Additionally, discontinuation of the fault indication causes BIST 116 to resume testing logic circuits 14 until diagnostic information collector 120 detects another fault or until BIST 116 reaches the end of the test sequence.

Concurrently with BIST 116 reaching the end of the test sequence, the main test routine executed by processing system 401 reaches the test result segment. The test result segment causes processing system 401 to supply the test result command to test channel 407. In response to the test result command, test channel 407 receives the test result from logic device under test 110 via test result input 33 and evaluates the test result by comparing the test result with the reference digital signature. Test channel 407 outputs the resulting category for logic device under test 110 to processing system 401. In this example, logic device under test 110 is categorized as bad. Since logic device under test 110 is categorized as bad, processing system 401 additionally outputs the diagnostic information received from logic device under test 110 and stored either in memory 422 or in a memory that constitutes part of diagnostic information channel 410.

In an alternative embodiment, test channel 407 is omitted and fault indication channel 409 additionally comprises an accumulator (not shown) coupled to the input circuit (not shown) that receives fault indication FI from fault indication port 136. The start of test command issued by processing system 401 at the beginning of the test sequence resets the accumulator. The first fault indication (if any) received at the input circuit of fault indication channel 409 changes the state of the output of the accumulator, and the output of the accumulator remains in the changed state until the end of the test sequence, regardless of the number of fault indications (if any) subsequently received.

The state of the output of the accumulator provides the test result for logic device under test 110. When the main test routine executed by processing system 401 reaches the above-described test result segment, processing system 401 evaluates the test result provided by the state of the output of the accumulator to categorize the logic device under test as good or bad. The output of the accumulator in its original state causes logic device under test 110 to be categorized as good, whereas the output in its changed state causes logic device under test 110 to be categorized as bad. Processing system 401 then outputs the category of device under test 110. Additionally, in the event that logic device under test 110 is categorized as bad, processing system 401 additionally outputs the diagnostic information received from logic device under test 110 and stored either in memory 422 or in a memory that constitutes part of diagnostic information channel 410. Alternatively, processing system 401 outputs a link indicating a location in ATE 412 where the diagnostic information for logic memory device under test 110 is stored.

The above-described embodiment of ATE 412 can easily be modified to allow ATE 412 to be used to receive diagnostic information from a memory device having a BIST and a diagnostic information collector, such as memory device 210 described above with reference to FIG. 3. Such an embodiment of ATE 412 has fewer processing channels than the example described above with reference to FIG. 6. Referring additionally to FIG. 3, an embodiment of ATE 412 suitable for testing a memory device has a test channel 407 for receiving and evaluating the test result output by diagnostic information collector 220; a test channel 411 for providing control signals and receiving control signals from BIST controller 226; a fault indication channel 409 for receiving fault indication FI and for providing and receiving control signals related to receiving the output of diagnostic information from diagnostic information collector 220; and a diagnostic information channel 410 for receiving the diagnostic information output from diagnostic information collector 220. Processing system 401 executes a main test routine suitable for testing memory devices. Test channel 407 may be omitted from embodiments of ATE 412 capable of determining a test result for the memory device under test instead of receiving a test result from the memory device under test itself.

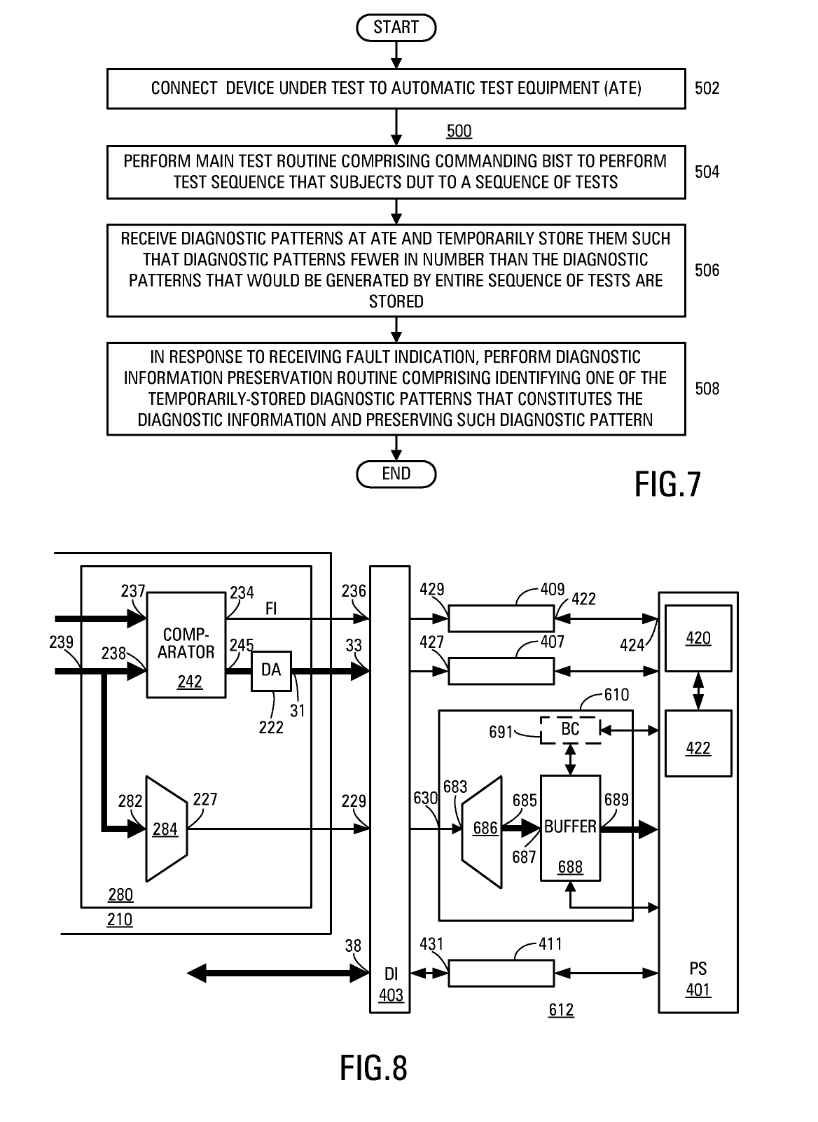

In the above-described examples of logic devices and memory devices each having a BIST and a diagnostic information collector, the diagnostic information collector temporarily stores at least one diagnostic pattern that provides diagnostic information. However, the diagnostic patterns may alternatively be temporarily stored in the ATE. FIG. 7 is a flow chart showing an example of a method 500 of operating automatic test equipment to obtain diagnostic information from a device under test having a built-in self-test system (BIST) and a diagnostic information collector. The BIST performs a sequence of tests to test the device under test and to generate respective diagnostic patterns. The diagnostic information collector provides a fault indication when an output pattern received from the BIST indicates a fault. The device under test is a logic device, a memory device or another type of device having a BIST and a diagnostic information collector.

In method 500, in block 502, the device under test is connected to the automatic test equipment. In block 504, a main test routine is performed. The main test routine comprises commanding the BIST to perform a test sequence that subjects the memory device under test to a sequence of tests.

In block 506, the diagnostic pattern resulting from each test performed by the BIST is received at the ATE and is temporarily stored. The diagnostic pattern is stored such that diagnostic patterns fewer in number than the diagnostic patterns that would be generated by the entire sequence of tests are stored.

In block 508, in response to receiving the fault indication, a diagnostic information preservation routine is executed. The diagnostic information output routine comprises identifying one of the temporarily-stored diagnostic patterns that constitutes the diagnostic information and preserving such diagnostic pattern. Alternatively, more than one of the temporarily-stored diagnostic patterns may be identified as constituting the diagnostic information and such diagnostic patterns preserved.

The diagnostic information preservation routine performed in block 508 identifies the one of the temporarily-stored diagnostic patterns that constitutes the diagnostic information and preserves such diagnostic pattern. The diagnostic pattern that constitutes the diagnostic information is the diagnostic pattern temporarily stored in a test cycle performed a predetermined number (including zero) of test cycles before the test cycle in which the fault indication was received. The predetermined number depends on the latency of the fault indication generation process. The diagnostic information preservation routine additionally preserves the diagnostic pattern that constitutes the diagnostic information by preventing such diagnostic pattern from being overwritten, being shifted out or otherwise being destroyed by subsequently-stored diagnostic patterns generated when performance of the main test routine resumes at the end of the diagnostic information preservation routine.

In one embodiment, the diagnostic information preservation routine preserves the temporarily-stored diagnostic pattern that constitutes the diagnostic information by outputting such diagnostic pattern from storage. The storage location from which the diagnostic pattern is output is determined by the above-described identifying operation. In another embodiment, the diagnostic information preservation routine preserves the temporarily-stored diagnostic pattern that constitutes the diagnostic information within the storage. The diagnostic pattern is preserved within the storage by prohibiting further write operations at the location of the diagnostic pattern in the storage or by moving the diagnostic pattern to a location in the storage where further write operations are prohibited, for example. The storage location subject to the write prohibition or the storage location from which the diagnostic pattern is moved to the write-protected location is determined by the above-described identifying operation.

FIG. 8 is a block diagram showing part of an example of memory device 210 having a BIST (not shown) and diagnostic information collector 280 that outputs the diagnostic patterns to the ATE for temporary storage. FIG. 8 additionally shows an example of an ATE 612 in accordance with an embodiment of the invention that may be used to test such memory device. Memory device 110, diagnostic information collector 120 and ATE 112 described above with reference to FIG. 1 may be similarly modified.

In diagnostic information collector 280, the output patterns read out from memory circuit 34 and received at output pattern input 239 provide respective diagnostic patterns. Diagnostic information collector 280 is composed of comparator 242 and difference accumulator 222, both described above with reference to FIG. 4A, and a multiplexer 284. Comparator 242 has an expected pattern input that provides the expected pattern input 237 of diagnostic information collector 280, an output pattern input 238 connected to the output pattern input 239 of diagnostic information collector 280, an output that provides the fault indication output 234 of diagnostic information collector 280 and a difference pattern output 245 connected to the input of difference accumulator 222. Multiplexer 284 has a parallel input 282 and a serial output. The serial output of multiplexer 284 provides the diagnostic information output 227 of diagnostic information collector 280. Parallel input 282 is connected to the output pattern input 239 of diagnostic information collector 280. Multiplexer 284 converts each output pattern it receives at parallel input 282 to a serial bit stream that it outputs at diagnostic information output 227.

Alternatively, in an embodiment of diagnostic information collector 280 based on diagnostic information collector 241 described above with reference to FIG. 4B in which difference patterns provide the respective diagnostic patterns, the parallel input 282 of multiplexer 284 is connected to the difference pattern output 245 of comparator 242. In this embodiment, multiplexer 284 converts each difference pattern output at difference pattern output 245 to provide the serial bit stream that it outputs at diagnostic information output 227.

ATE 612 tests embodiments of memory device 210 that incorporate diagnostic information collector 280. ATE 612 comprises processing system (PS) 401, device interface (DI) 403 and processing channels 407, 409 and 411, all of which are similar to the corresponding elements described above with reference to FIG. 6. ATE 612 additionally comprises a diagnostic information channel 610 comprising a demultiplexer 686 and a buffer 688.

Demultiplexer 686 has a serial input 683 and a parallel output 685. Serial input 683 is connected to the diagnostic information input 630 of processing channel 610. Diagnostic information input 630 is connected via device interface 403 to the diagnostic information input 229 of ATE 612. In this embodiment, diagnostic information input 229 is a serial input.

Buffer 688 has a diagnostic pattern input 687 connected to the parallel output 685 of demultiplexer 686. Buffer 688 additionally has a diagnostic information output 689 via which it outputs at least some of the diagnostic patterns stored therein to the processing system 401 of ATE 612 as diagnostic information for analysis and/or storage. Alternatively, a buffer capable of storing a serial bit stream may be used as buffer 688. In such an embodiment, demultiplexer 686 is omitted.

Also shown in FIG. 8 is an optional buffer controller (BC) 691 that operates in response to fault indication FI received at fault indication channel 409 and forwarded to diagnostic information channel 610 by processing system 401. Buffer controller 691 operates in response to fault indication FI to control the operation of buffer 688 to identify one of the diagnostic patterns temporarily stored in the buffer as diagnostic information and to preserve such diagnostic pattern. Alternatively, more than one of the diagnostic patterns may be identified as diagnostic information and be preserved. Buffer controller 691 is in turn controlled by processing system 401 or by a processor (not shown) that constitutes part of diagnostic information channel 610. Circuits suitable for use as buffer controller 691 are known in the art. Accordingly, the structure of buffer controller 691 will not be described. Alternatively, processing system 401 or the above-described processor that constitutes part of diagnostic information channel 610 operates in response to fault indication FI received at fault indication channel 409 to control the operation of buffer 688 to perform the above-described function. In this case, buffer controller 691 is omitted. Buffer 688, processing system 401 or the above-described processor that constitutes part of diagnostic information channel 610, and, optionally, buffer controller 691 collectively constitute a structure that performs the function of identifying one of the diagnostic patterns temporarily stored in buffer 688 as constituting the diagnostic pattern and preserving the one of the diagnostic patterns.

ATE 612 operates deterministically with respect to the diagnostic patterns received at diagnostic information input 229, i.e., the main test routine performed by processing system 401 causes diagnostic information channel 610 to receive, demultiplex (if necessary) and store temporarily in buffer 688 each diagnostic pattern received at the diagnostic information input 229 of device interface 403. Specifically, ATE 612 receives a serial bitstream representing each diagnostic pattern at diagnostic information input 229 connected via device interface 403 to diagnostic information channel 610. In diagnostic information channel 610, demultiplexer 686 demultiplexes the serial bitstream to generate respective diagnostic patterns and buffer 688 temporarily stores the diagnostic patterns in buffer 688 such that diagnostic patterns fewer in number than the diagnostic patterns that would be generated by the entire test sequence are stored. The number of the diagnostic patterns stored, and, hence, the minimum size of buffer 688, depend on the maximum number of tests BIST 216 performs before it can suspend its normal testing operations in response to fault indication FI.

When ATE 612 tests a fault-free example of memory device under test 210, each output pattern is identical to its corresponding expected pattern so that BIST 216 reaches the end of the test sequence without diagnostic information collector 280 generating fault indication FI. Concurrently with BIST 216 reaching the end of the test sequence, the main test routine executed by processing system 401 reaches its test result segment. The test result segment causes processing system 401 to supply the test result command to test channel 407. In response to the test result command, test channel 407 receives the cumulative difference output by memory device under test 210 as the test result for memory device under test 210. Processing system 401 evaluates the test result to categorize memory device under test 210 as good or bad. Since the test result indicates that no difference has been detected, this example of memory device under test 210 is categorized as good. Alternatively, processing system categorizes this example of memory device under test 210 as good by determining that fault indication channel 409 has received no fault indication FI while memory device under test 210 was being tested, as described above.

When ATE 612 tests an example of memory device under test 210 having at least one fault, at least one output pattern differs from its corresponding expected pattern, and, for each output pattern that differs from its corresponding expected pattern, diagnostic information collector 220 provides fault indication FI to fault indication channel 409 of ATE 612. As in the above-described ATE embodiments, ATE 612 operates non-deterministically with respect to fault indication FI received from memory device under test 210 at fault indication channel 409. Fault indication FI, which device under test 210 can output at any one or more points in the test sequence, causes BIST 216 to suspend its normal testing operations, as described above. Additionally, ATE 612 receives fault indication FI at fault indication input 236 and fault indication channel 409. Fault indication FI causes processing system 401 to suspend execution of the main test routine and to execute a diagnostic information preservation routine instead. The diagnostic information preservation routine causes processing system 401 to provide a control signal to diagnostic information channel 610. Directly or via buffer controller 691, the control signal causes buffer 688 to perform a diagnostic pattern preservation operation in which it identifies one of the diagnostic patterns temporarily stored therein that constitutes the diagnostic information and preserves such diagnostic pattern.

When the diagnostic pattern constituting the diagnostic information has been identified and preserved, the diagnostic pattern preservation routine ends, and processing system 401 instructs BIST 216 via BIST controller 226 and test channel 411 to resume its normal testing operations, and processing system 401 resumes execution of the main test routine. Other fault indications may be generated after execution of the main test routine has resumed. Such fault indications cause respective suspensions of execution of the main test routine and respective executions of the diagnostic information preservation routine, as described above.

Processing system 401 reaches the test result segment at end of the main test routine concurrently with BIST 216 reaching the end of the test sequence. In this example, the test result segment performed by processing system 401 causes test channel 407 to receive the cumulative difference from memory device under test 210 as the test result for memory device under test 210. Processing system 401 evaluates the test result to categorize memory device under test 210 as good or bad. Processing system 401 categorizes this example of memory device under test 210 as bad. Alternatively, processing system 401 may categorize memory device under test 210 as good or bad based on whether fault indication FI was received at fault indication channel 409 while memory device under test 210 was being tested, as described above. Processing system 401 outputs the category of memory device under test 210 and, when memory device under test is categorized as bad, processing system 401 additionally outputs the diagnostic information for memory device under test 210.

In ATE 612, the diagnostic information preservation routine executed by processing system 401 identifies the diagnostic pattern temporarily stored in buffer 688 that constitutes the diagnostic information by identifying a location in buffer 688 at which a diagnostic pattern was stored a predetermined number (including zero) of test cycles before the test cycle in which the fault indication was received. The predetermined number depends on the latency of the fault indication generation process. In some embodiments, the diagnostic information preservation routine identifies and preserves more than one diagnostic pattern as the diagnostic information. Then, the diagnostic information preservation routine causes buffer 688 controlled by buffer controller 692 or buffer 688 directly controlled by processing system 401 to preserve the diagnostic pattern that constitutes the diagnostic information by preventing such diagnostic pattern from being overwritten, being shifted out or otherwise being destroyed by a diagnostic pattern subsequently stored in buffer 688 when execution of the main test routine is resumed after the diagnostic information preservation routine has been performed.

In an embodiment, buffer 688 preserves each diagnostic pattern identified as constituting the diagnostic information by outputting such diagnostic pattern to storage (not shown) external to buffer 688. As memory device under test 210 is tested, the diagnostic information for the memory device under test accumulates in such storage. In an embodiment, the diagnostic information is output from buffer 688 to a memory (not shown) constituting part of diagnostic information channel 610. In the event that the test result segment of the main test routine categorizes the memory device under test as bad, processing system 401 causes the accumulated diagnostic information to be output from the storage external to buffer 688 as the diagnostic information for the memory device under test.

In another embodiment, buffer 688 preserves each diagnostic pattern identified as constituting the diagnostic information by preventing write operations at locations where such diagnostic pattern is stored. Write operations at the location where the diagnostic pattern identified as constituting the diagnostic information is temporarily stored can be prohibited. Alternatively, the diagnostic pattern identified as constituting the diagnostic information can be moved to a region within buffer 688 where write operations are prohibited. As memory device under test 210, the diagnostic information for the memory device under test is accumulated in such write-protected region within buffer 688. In the event that the test result segment of the main test routine categorizes the memory device under test as bad, processing system 401 causes the accumulated diagnostic information to be output from the write-protected region in buffer 688 as the diagnostic information for the memory device under test.

This disclosure describes the invention in detail using illustrative embodiments. However, the invention defined by the appended claims is not limited to the precise embodiments described.

We claim:

1. Automatic test equipment capable of receiving diagnostic information from a device under test, the device under test comprising a built-in self-test system (BIST) and a diagnostic information collector, the diagnostic information collector temporarily storing diagnostic patterns output by the BIST and providing a fault indication upon detecting a fault in the device under test, the automatic test equipment comprising:
a device interface connectable to the device under test;
a processing system; and
processing channels each connected to the device interface and to the processing system, the processing channels comprising:
test channels interoperable with the BIST to subject the device under test to a sequence of tests,
a fault indication channel connected to receive the fault indication from the device interface, and
a diagnostic information channel operable in response to the fault indication received at the fault indication channel to receive from the device interface at least some of the diagnostic patterns temporarily stored in the device under test as the diagnostic information.

2. The automatic test equipment of claim 1, in which the fault indication received at the fault indication channel additionally causes the test channels to suspend subjecting the device under test to the sequence of tests prior to the diagnostic patterns being received via the diagnostic information channel.

3. The automatic test equipment of claim 1, in which:
the processing system executes a main test routine that causes the test channels to subject the device under test to the sequence of tests;
the processing system has an interrupt input coupled to the fault indication channel; and
the fault indication causes the processing system to interrupt execution of the main test routine and to execute a diagnostic information receiving routine that causes the diagnostic information channel to receive the diagnostic patterns.

4. The automatic test equipment of claim 1, in which:
the processing system executes a main test routine that causes the test channels to subject the device under test to the sequence of tests;
the main test routine repetitively checks for presence of the fault indication at the fault indication channel; and
the main test routine detecting the presence of the fault indication at the fault indication channel causes the processing system to suspend execution of the main test routine and to execute a diagnostic information receiving routine that causes the diagnostic information channel to receive the diagnostic patterns.

5. The automatic test equipment of claim 1, in which the diagnostic information channel comprises a demultiplexer.

6. The automatic test equipment of claim 1, in which one of the processing channels is additionally operable to provide an indication to the device under test that the diagnostic information channel is ready to receive the diagnostic patterns.

7. The automatic test equipment of claim 1, in which the one of the test channels is operable to receive a test result from the device under test, to evaluate the test result and to provide a test result for the device under test to the processing system.

8. The automatic test equipment of claim 1, in which the fault indication channel is additionally operable to provide a test result for the device under test.

9. Automatic test equipment capable of receiving diagnostic information from a device under test, the device under test comprising a built-in self-test system (BIST) and a diagnostic information collector that provides a fault indication upon detecting a fault in the device under test, the automatic test equipment comprising:
a device interface connectable to the device under test;
a processing system;
processing channels connected to the device interface and to the processing system, the processing channels comprising:
test channels interoperable with the BIST to subject the device under test to a sequence of tests,
a fault indication channel connected to receive a fault indication from the device interface, and
a diagnostic information channel connected to the device interface to receive diagnostic patterns output by the BIST, the diagnostic information channel comprising a buffer operable to store temporarily the diagnostic patterns such that diagnostic patterns fewer in number than the diagnostic patterns that would be generated by the entire sequence of tests are stored; and
diagnostic information preserving means, operable in response to the fault indication received at the fault indication channel, for identifying one of the temporarily-stored diagnostic patterns as the diagnostic information and for preserving the one of the diagnostic patterns.

10. The automatic test equipment of claim 9, in which fault indication received at the fault indication channel additionally causes the test channels to suspend subjecting the device under test to the test sequence prior to the diagnostic patterns being output as the diagnostic information.

11. The automatic test equipment of claim 9, in which:
the processing system executes a main test routine that causes the test channels to subject the device under test to the sequence of tests;
the processing system has an interrupt input coupled to the fault indication channel; and
the fault indication causes the processing system to suspend execution of the main test routine and to execute a diagnostic information output routine that causes the buffer to output the diagnostic patterns as the diagnostic information.

12. The automatic test equipment of claim 9, in which:
the processing system executes a main test routine that causes the test channels to subject the device under test to the sequence of tests;
the main test routine additionally repetitively detects presence of the fault indication at the fault indication channel;
the main test routine detecting the presence of the fault indication at the fault indication channel causes the processing system to suspend execution of the main test routine and to execute a diagnostic information outputting routine that causes the buffer to output the diagnostic patterns as the diagnostic information.

13. The automatic test equipment of claim 9, in which the diagnostic information preserving means is additionally for causing the buffer to output the diagnostic pattern identified as constituting the diagnostic pattern to preserve the diagnostic pattern.

14. The automatic test equipment of claim 9, in which the diagnostic information preserving means is additionally for preventing the diagnostic pattern temporarily stored in the buffer and identified as the diagnostic information from being destroyed by diagnostic patterns subsequently stored in the buffer.

15. A method of operating automatic test equipment (ATE) to obtain diagnostic information from a device under test, the device under test comprising a built-in self-test system (BIST) and a diagnostic information collector, the BIST performing a sequence of tests to test the device under test, the diagnostic information collector providing a fault indication when an output pattern received from the BIST indicates a fault, and additionally temporarily storing diagnostic patterns, the method comprising:
connecting the device under test to the automatic test equipment;
performing a main test routine comprising commanding the BIST to perform a test sequence that tests the device under test; and
in response to receiving the fault indication, performing a diagnostic information receiving routine comprising receiving at least some of the temporarily-stored diagnostic patterns from the device under test, the diagnostic patterns received being fewer in number than the diagnostic patterns that would be generated by the entire test sequence, at least one of the received diagnostic patterns constituting diagnostic information.

16. The method of claim 15, in which the main test routine additionally comprises:
at the end of the sequence of tests, receiving from the diagnostic information collector a test result for the device under test; and
evaluating the test result.

17. The method of claim 15, in which the diagnostic information temporarily stored in the diagnostic information collector comprises diagnostic patterns generated by the device under test in response to stimuli provided by the BIST.

18. The method of claim 15, in which the fault indication interrupts execution of the main test routine and causes the diagnostic information receiving routine to be executed.

19. The method of claim 18, additionally comprising resuming execution of the main test routine after the diagnostic information receiving routine has been executed.

20. The method of claim 15, in which:
the main test routine additionally comprises repetitively testing for a presence of the fault indication; and
the diagnostic information receiving routine is executed when the testing determines that the fault indication is present.

21. The method of claim 20, additionally comprising resuming execution of the main test routine after the diagnostic information receiving routine has been executed.

22. The method of claim 15, in which the receiving additionally comprises receiving the diagnostic patterns as a serial bit stream.

23. The method of claim 15, in which the device under test comprises a logic circuit.

24. The method of claim 15, in which the device under test comprises a memory circuit.

25. A method of operating automatic test equipment (ATE) to obtain diagnostic information from a device under test, the device under test comprising a built-in self-test system (BIST) and a diagnostic information collector, the BIST performing a sequence of tests to test the device under test and to generate respective diagnostic patterns, the diagnostic information collector providing a fault indication when an output pattern received from the BIST indicates a fault, the method comprising:
connecting the device under test to the automatic test equipment;
performing a main test routine comprising commanding the BIST to perform a test sequence that tests the device under test;
receiving the diagnostic patterns at the ATE and temporarily storing them such that diagnostic patterns fewer in number than the diagnostic patterns that would be generated by the entire sequence of tests are stored; and
in response to receiving the fault indication, performing a diagnostic information preservation routine comprising identifying one of the temporarily-stored diagnostic patterns as constituting the diagnostic information and preserving the one of the diagnostic patterns.

26. The method of claim 25, in which the fault indication interrupts execution of the main test routine and causes the diagnostic information preservation routine to be executed.

27. The method of claim 26, additionally comprising resuming execution of the test routine after the diagnostic information preservation routine has been executed.

28. The method of claim 25, in which:
the main test routine additionally comprises repetitively testing for a presence of the fault indication; and
the diagnostic information preservation routine is executed when the testing determines that the fault indication is present.

29. The method of claim 28, additionally comprising resuming execution of the main test routine after the diagnostic information preservation routine has been executed.

30. The method of claim 25, in which the device under test comprises a logic circuit.

31. The method of claim 25, in which the device under test comprises a memory circuit.

32. The method of claim 25, in which:
the ATE comprises a buffer in which the diagnostic patterns are temporarily stored; and
the preserving comprises outputting from the buffer the one of the diagnostic patterns identified as constituting the diagnostic information.

33. The method of claim 25, in which:
the ATE comprises a buffer in which the diagnostic patterns are temporarily stored; and
the preserving comprises protecting the one of the diagnostic patterns identified as constituting the diagnostic information from being destroyed by diagnostic patterns subsequently stored in the buffer.
